(19) United States
(12) Patent Application Publication
(10) Pub. No.: US 2026/0352217 A1
(43) Pub. Date: Nov. 5, 2026

(54) BACKGROUND CALIBRATION OF A CLOCK RECOVERY CIRCUIT IN A C-PHY RECEIVER

(71) Applicant: QUALCOMM Incorporated, San Diego, CA (US)

(72) Inventors: Abhay DIXIT, San Diego, CA (US); Ying DUAN, San Diego, CA (US); Qinqing CAO, San Diego, CA (US); Sachin Ajit DEVAMARE, San Diego, CA (US); Yasser AHMED, San Diego, CA (US)

(21) Appl. No.: 19/197,702

(22) Filed: May 2, 2025

(51) Int. Cl. H03L 7/08; H04L 7/033

(52) U.S. Cl. CPC H03L 7/0807; H04L 7/033

(57) ABSTRACT

A clock recovery circuit includes a calibration circuit and clock generation subcircuits that each includes a flipflop and a delay circuit. The flipflops are clocked by pulses initiated by transitions in difference signals representative of signaling state of pairs of wires in a C-PHY communication link. Each delay circuit is configured to delay an output of a corresponding flipflop and to provide a reset signal to the corresponding flipflop. The delay circuit in the second clock generation subcircuit may be calibrated while the first clock generation subcircuit operates normally. Calibration includes comparing frequencies of signal output by the clock generation subcircuits, identifying a block of calibration codes corresponding to an eye opening and configuring the delay circuit in the first clock generation subcircuit using a calibration code in the block of calibration codes that encodes a median calibration value.

### TECHNICAL FIELD

The present disclosure relates generally to serial communication over a serial bus in a wireless communication device and, more particularly, to clock and data recovery circuits used in a C-PHY interface.

### BACKGROUND

Mobile communication devices typically include a variety of components such as circuit boards, integrated circuit (IC) devices, application-specific integrated circuit (ASIC) devices and/or System-on-Chip (SoC) devices. The types of components may include processing circuits, user interface components, storage and other peripheral components that communicate over a serial bus. The serial bus may be operated in accordance with a standardized or proprietary protocol.

Multiple standards are defined for interconnecting certain types of components in mobile communication devices. For example, different types of interfaces may be used for communication between an application processor and display or camera components in a mobile communication device. Some display or camera components employ an interface that conforms to standards or protocols specified by the Mobile Industry Processor Interface (MIPI) Alliance for a camera serial interface (CSI) and a display serial interface (DSI). The MIPI Alliance DSI, DSI-2 (referred to individually or collectively herein as DSI) and CSI and CSI-2 (referred to individually or collectively herein as CSI) standards define wired interfaces that can be deployed within an IC or between some combination of IC devices and SoC devices. CSI protocols may be used to couple a camera and application processor. DSI protocols may be used to couple an application processor and display subsystem.

The CSI and DSI may employ a low-level physical-layer (PHY) interface defined by the MIPI Alliance C-PHY standard and protocols. A C-PHY receiver typically generates a receive clock signal by detecting transitions in signaling state of the received data signals. The quality of the timing information provided by the receive clock signal can be adversely affected by jitter, and timing issues tend to increase with data transmission rates, which provide lower tolerance for edge timing. Accordingly, there is an ongoing need for improved clock and data recovery circuits.

### SUMMARY

Certain aspects of the disclosure relate to systems, apparatus, methods and techniques that can improve common mode noise rejection at receivers coupled to a C-PHY three-wire communication link.

In various aspects of the disclosure, a clock recovery circuit includes a first clock generation subcircuit, a second clock generation subcircuit and a calibration subcircuit. The first clock generation subcircuit includes a first flipflop that is clocked by pulses initiated by transitions in difference signals, and a first delay circuit that delays an output of the first flipflop to provide a first reset signal that resets the first flipflop. Each difference signal is representative of signaling state of one pair of wires in a three-wire serial communication link. The second clock generation subcircuit includes a second flipflop that is clocked by the pulses, and a second delay circuit that delays an output of the second flipflop to provide a second reset signal that resets the second flipflop. The calibration subcircuit may be configured to iteratively modify duration of a delay provided by the second delay circuit while the first clock generation subcircuit is generating a receive clock signal used to capture signaling state of the difference signals, compare a frequency of the receive clock signal with a frequency of a calibration clock signal output by the second clock generation subcircuit, during each iteration, and modify a duration of the delay provided by the first delay circuit based on comparisons of frequencies of the receive clock signal and the calibration clock signal.

In various aspects of the disclosure, a method for recovering clock signals, includes clocking a first flipflop and a second flipflop using a pulse that is initiated by a transition in difference signals occurring at the beginning of a symbol transmission interval, delaying an output of the first flipflop to provide a first reset signal that resets the first flipflop, delaying an output of the second flipflop to provide a second reset signal that resets the second flipflop, iteratively modifying duration of a delay provided by a delay circuit that provides the second reset signal while the first flipflop is generating a receive clock signal used to capture signaling state of the difference signals, comparing frequencies of the receive clock signal and a calibration clock signal output by the second flipflop, during each iteration, and modifying a duration of the delay provided by a delay circuit that provides the first reset signal based on comparisons of frequencies of the receive clock signal and the calibration clock signal. Each difference signal represents signaling state of one pair of wires in a three-wire serial communication link.

In various aspects of the disclosure, an apparatus includes means for generating pulses in response to first-occurring transitions in difference signals and means for calibrating a first delay circuit in a first clock generation subcircuit. Each difference signal may represent signaling state of one pair of wires in a three-wire serial communication link. In one example, the means for calibrating the delay circuit in the first clock generation subcircuit includes a second clock generation subcircuit and a calibration subcircuit. The calibration subcircuit may be configured to iteratively modify duration of a delay provided by a second delay circuit while the first clock generation subcircuit is generating a receive clock signal used to capture signaling state of the difference signals, compare a frequency of the receive clock signal with a frequency of a calibration clock signal output by the second clock generation subcircuit, during each iteration, and modify a duration of the delay provided by the first delay circuit based on comparisons of frequencies of the receive clock signal and the calibration clock signal.

In certain aspects, each of the pulses is initiated by a transition occurring at the beginning of a symbol transmission interval. The duration of the delay provided by the first delay circuit is configured to suppress additional transitions occurring at the beginning of the symbol transmission interval without suppressing a transition at the beginning of a next and immediately following symbol transmission interval.

In certain aspects, the calibration subcircuit is configured to modify the duration of the delay provided by the second delay circuit in each iteration by incrementally modifying a calibration codeword used to configure duration of the delay provided by the second delay circuit, and identify a block of calibration codewords that cause the frequency of the calibration clock signal to match the frequency of the receive clock signal. The calibration subcircuit may be configured to modify the duration of the delay provided by the first delay circuit by configuring the first delay circuit with a codeword that corresponds to a median value of the block of calibration codewords.

In certain examples, a first block of calibration codewords causes the frequency of the calibration clock signal to be greater than the frequency of the receive clock signal, a second block of calibration codewords causes the frequency of the calibration clock signal to match the frequency of the receive clock signal, and a third block of calibration codewords causes the frequency of the calibration clock signal to be less than the frequency of the receive clock signal. In one example, each calibration codeword in the second block of calibration codewords encodes a value that is greater than the value encoded by each calibration codeword in the first block of calibration codewords and less than the value encoded by each calibration codeword in the third block of calibration codewords. In another example, each calibration codeword in the second block of calibration codewords encodes a value that is less than the value encoded by each calibration codeword in the first block of calibration codewords and greater than the value encoded by each calibration codeword in the third block of calibration codewords.

According to one aspect, the three-wire serial communication link is operated in accordance with a Mobile Industry Processor Interface (MIPI) Alliance C-PHY protocol.

### BRIEF DESCRIPTION OF THE DRAWINGS

FIG. 1 illustrates an example of a system-on-a-chip in accordance with certain aspects of the present disclosure.

FIG. 2 illustrates an apparatus employing interconnected chiplets.

FIG. 3 illustrates an example of an apparatus in which chiplets are stacked vertically on a substrate.

FIG. 4 illustrates an example of a C-PHY interface that may be adapted according to certain aspects disclosed herein.

FIG. 5 is state diagram illustrating signaling states and transitions between signaling states in a C-PHY interface implemented in accordance with certain aspects disclosed herein.

FIG. 6 illustrates an example of a clock recovery circuit that may be implemented in a CDR of a C-PHY receiver.

FIG. 7 illustrates certain aspects of the timing associated with the clock recovery circuit illustrated in FIG. 6.

FIG. 8 illustrates an example of a CDR that may be implemented, configured or dynamically calibrated in accordance with certain aspects of this disclosure.

FIG. 9 illustrates certain aspects of a CDR code calibration procedure that may be implemented in accordance with certain aspects of this disclosure.

FIG. 10 illustrates an example of an apparatus employing a processing circuit that may be adapted according to certain aspects disclosed herein.

FIG. 11 is a flowchart of a method for recovering clock signals embedded in signaling received over a multi-wire serial bus in accordance with certain aspects of this disclosure.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well-known structures and components are shown in block diagram form in order to avoid obscuring such concepts.

Several aspects of the invention will now be presented with reference to various apparatus and methods. These apparatus and methods will be described in the following detailed description and illustrated in the accompanying drawings by various blocks, modules, components, circuits, steps, processes, algorithms, etc. (collectively referred to as “elements”). These elements may be implemented using electronic hardware, computer software, or any combination thereof. Whether such elements are implemented as hardware or software depends upon the particular application and design constraints imposed on the overall system.

Data communication links employed by SoCs and other IC devices to connect processors with modems and other peripherals may be operated in accordance with industry or proprietary standards or protocols associated with certain functions or types of devices. In the example of display panels, display subsystems, and display drivers, communication standards and protocols defined by the Mobile Industry Processor Interface (MIPI) Alliance are frequently used. The Camera Serial Interface (CSI®) and Display Serial Interface (DSI®) standards defined by the MIPI Alliance provide C-PHY standards and protocols that define, configure and control operation of a high-speed serial interface that may be deployed between a host processor and a camera and between a host processor and a display module.

Serial data links, including links operated in accordance with C-PHY protocols, may be used to interconnect electronic devices that are subcomponents of an apparatus such as a cellular phone, a smart phone, a session initiation protocol (SIP) phone, a laptop, a notebook, a netbook, a smartbook, a personal digital assistant (PDA), a satellite radio, a global positioning system (GPS) device, a smart home device, intelligent lighting, a multimedia device, a video device, a digital audio player (e.g., MP3 player), a camera, a game console, an entertainment device, a vehicle component, a wearable computing device (e.g., a smart watch, a health or fitness tracker, eyewear, etc.), an appliance, a sensor, a security device, a vending machine, a smart meter, or any other similar functioning device.

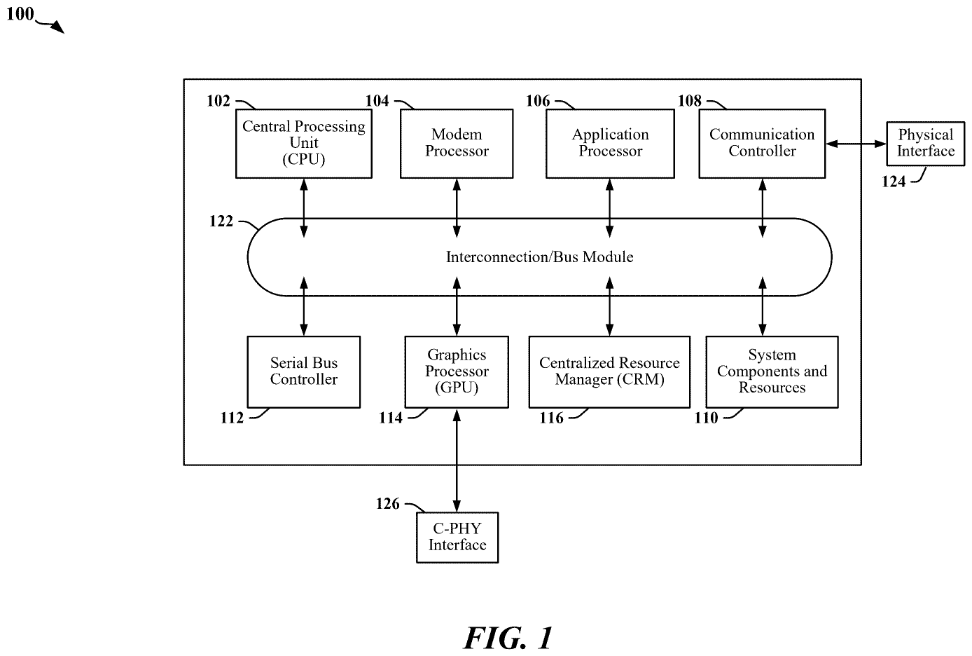

FIG. 1 illustrates an example of an apparatus 100 in which certain components and interconnections can be implemented in an SoC. The apparatus 100 may include a number of heterogeneous processors, such as a central processing unit (the CPU 102), a modem processor 104, an application processor 106 and a graphics processor 114. Each processor 102, 104, 106, 114, may include one or more cores, and each processor/core may perform operations independent of the other processors/cores. The processors 102, 104, 106, 114 may be provided in close proximity to one another (e.g., on a single substrate, die, integrated chip, etc.) so that the processors may operate at a much higher frequency/clock rate than would be possible if the signals were to travel off-chip. The proximity of the cores may also allow for the sharing of on-chip memory and resources (e.g., power/voltage rails), as well as for more coordinated cooperation between cores.

The apparatus 100 may include system components and resources 110 for managing sensor data, analog-to-digital conversions, and/or wireless data transmissions, and for performing other specialized operations (e.g., decoding high-definition video, video processing, etc.). System components and resources 110 may also include components such as voltage regulators, oscillators, phase-locked loops (PLLs), peripheral bridges, data controllers, system controllers, access ports, timers, and/or other similar components used to support the processors and software clients running on the computing device. The system components and resources 110 may also include circuitry for interfacing with peripheral devices, such as cameras, electronic displays, wireless communication devices, external memory chips, etc.

The apparatus 100 may further include a serial bus controller 112 such as a Universal Serial Bus (USB) controller, a communication controller 108, and a centralized resource manager (CRM) 116. The apparatus 100 may also include an input/output module (not illustrated) for communicating with resources external to the SoC, each of which may be shared by two or more of the internal SoC components.

The processors 102, 104, 114, 106 may be interconnected to the serial bus controller 112, the communication controller 108, system components and resources 110, CRM 116, and/or other system components via an interconnection/bus module 122, which may include an array of reconfigurable logic gates and/or implement a bus architecture. Communications may also be provided by advanced interconnects, such as high-performance networks on chip (NoCs).

The interconnection/bus module 122 may include or provide a bus mastering system configured to grant SoC components (e.g., processors, peripherals, etc.) exclusive control of the bus (e.g., to transfer data in burst mode, block transfer mode, etc.) for a set duration, number of operations, number of bytes, etc. In some cases, the interconnection/bus module 122 may implement an arbitration scheme to prevent multiple master components from attempting to drive the bus simultaneously. The communication controller 108 may be a specialized hardware module configured to manage and/or prioritize the flow of data to and from a physical interface 124. In one example, the physical interface 124 includes a radio frequency integrated circuit (RFIC). In other examples, the physical interface 124 may support a parallel and/or serial interface configured to support communication with external integrated circuits. In the illustrated example, the graphics processor 114 may be configured to communicate with one or more cameras and/or one or more display systems through a C-PHY interface 126.

The communication controller 108 may include one or more processors configured to perform operations with the physical interface 124, often within time constraints specified or required by communication standards and protocols. Examples of processors include microprocessors, microcontrollers, digital signal processors (DSPs), field programmable gate arrays (FPGAs), programmable logic devices (PLDs), state machines, gated logic, discrete hardware circuits, and other suitable hardware configured to perform the various functionality described throughout this disclosure. In certain aspects, the physical interface 124 may be part of the apparatus 100.

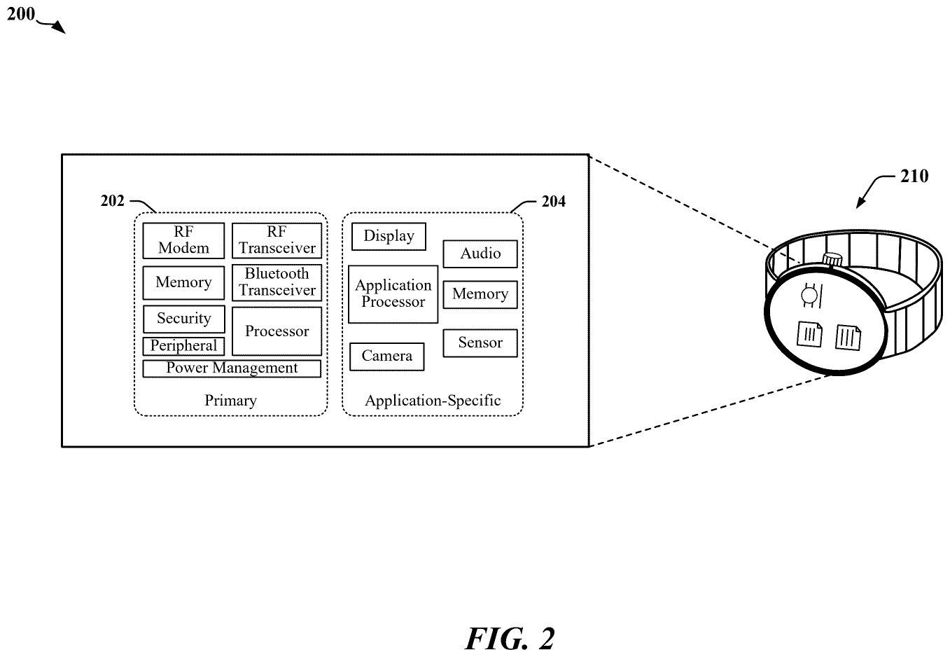

FIG. 2 illustrates an example of an apparatus 200 in which certain components are implemented using multiple chiplets that are interconnected using one or more data communication buses. In one example, the apparatus 200 may be enclosed within a wearable device a portable or wearable processing and/or communication device (each of which being referred to herein as a portable communication device or PCD), sensors, instruments, appliances and other such devices include one or more ICs. These devices may include mobile phones, tablet computers, palmtop computers, portable digital assistants (PDAs), portable game consoles, and other portable electronic devices such as the illustrated smartwatch 210. PCDs commonly contain integrated circuits or SoCs that include numerous components or subsystems designed to work together to deliver functionality to a user. The various SoC subsystems may communicate with each other via one or more intra-chip data buses or similar data communication interconnects. PCDs may have multiple SoCs that communicate with each other via similar inter-chip interconnects. The ICs are typically packaged in an IC package, which may be referred to as a “semiconductor package” or “chip package.” The IC package typically includes a package substrate and one or more IC chips or other electronic modules mounted to the package substrate to provide electrical connectivity to the IC chips. For example, an IC chip in an IC package may be configured as an SoC. The IC chips are electrically coupled to other IC chips and/or to other components in the IC package through electrical coupling to metal lines in the package substrate. The IC chips can also be electrically coupled to other circuits outside the IC package through electrical connections of external metal interconnects (e.g., solder bumps) of the IC package.

Chiplet technology can be used to address some of the performance, power and size design requirements for complex SoCs used in certain mobile or wearable devices. The block diagram in FIG. 2 illustrates certain aspects of an apparatus 200 that can be constructed using chiplets. The apparatus 200 may be configured by selecting a combination of chiplets that implement certain subsystems or distinct functional elements. In the illustrated example, the apparatus 200 includes a set of primary chiplets 202 that enable the apparatus 200 to perform core processing, security and communication functions. The set of primary chiplets 202 include a processor, memory and one or more modems. The illustrated apparatus 200 also includes a set of application-specific chiplets 204 that includes an application processor, display driver, camera interface and audio controller. In a remote sensing device or appliance, the audio-visual components could be omitted and may be replaced with analog-to-digital controllers, for example.

The apparatus 200 may include a variety of processing engines, such as central processing units (CPUs) with multiple cores, graphical processing units (GPUs), digital signal processors (DSPs), neural processing units (NPUs), wireless transceiver units (also referred to as modems), peripherals, display and imaging interfaces, etc. Each of these subsystems and other functional elements can be implemented as an individual chiplet, or as a combination of chiplets. The chiplets included in the apparatus 200 can be proprietary or may be acquired from a variety of sources. An SoC may be constructed from chiplets manufactured at different process nodes and/or operated at different voltages.

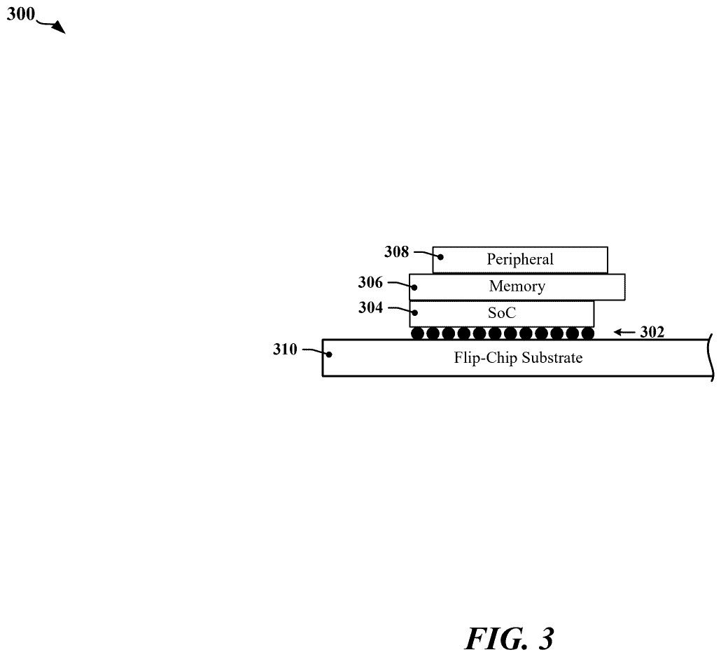

FIG. 3 illustrates an example of an SoC 300 in which certain chiplets 304, 306, 308 are stacked vertically on a substrate 310. Some chiplets can be included in stacks that are deployed across the surface of the substrate 310, while other chiplets may be individually mounted on the surface of the substrate. Chiplets may be mounted on the surface of the substrate using solder balls 302 that provide electrical and/or thermal coupling between substrate and the mounted chiplets. An interconnect structure may be formed that enables chiplets 304, 306, 308 in a stack of chiplets to communicate with one another, with other chiplets mounted on the substrate 310 and with input/output structures that connect the apparatus 200 with other circuits, displays, imaging sensors and other peripherals with an apparatus.

The use of chiplets can reduce the areal size of the substrate 310 and increase three-dimensional packing density. The constituent chiplets may provide complex features and high performance within a smaller form-factor operated at lower power specifications. Moreover, each chiplet may define multiple power domains, operate at different frequencies and different chiplets may manage power/frequency modes independently and. In some instances, two or more chiplets may be operated in mutually exclusive power states. Additionally, operating conditions for an SoC depend on the type, number and arrangement of chiplets included on the substrate in addition to the modes of operation defined by applications. It is necessary to consider power usage by all chiplets in the SoC in order to ensure compliance with power budgets assigned for an application or device.

Conventional chiplet-based implementations suffer from limitations that include complex or difficult interconnect routing, local hotspots arising from routing congestion caused by connection architecture and challenges to signal timing specifications. In certain examples, local hotspots can arise from routing congestion, increased feature complexity and circuit concentrations. In certain examples, signal timing specifications can be compromised due to the necessity for an increased number of isolation clamps due to logic placement, number of voltage domains and reduced floorplan. Long wire crossings between chiplets can cause routing congestion.

Each chiplet in an SoC may be included to perform a specific function or type of function and the configuration of the chiplets can introduce further complexities and challenges for designers. For example, one chiplet may include radio frequency front end circuits that produce high frequency signals ranging up to 5 GHz or more, and may further include interfaces that are used by low-frequency power management circuits. A designer may import previously defined circuit blocks to implement some of the internal functions. These circuit blocks may be referred to as macros. Imported circuit blocks for a given process technology may be described, characterized or defined by a set of masks, hardware description language, specifications and test data. Commercially available or proprietary circuit blocks may be referred to as hard macros. Hard macros are tested and verified for a set of design and operating specifications. It is common for hard macros and other circuit blocks to define multiple power domains.

Systems and apparatus provided in accordance with certain aspects of this disclosure implement a physical layer interface using MIPI Alliance-defined C-PHY standards and protocols (i.e., a C-PHY interface). The C-PHY interface may be used to connect a camera or a display system to an application processor. The C-PHY interface may be characterized as a multi-phase data encoding and decoding interface. A multi-phase encoder may drive a plurality of conductors (i.e., 3 conductors). Each conductor may be referred to as a wire, although the conductors may include conductive traces on a circuit board or traces or interconnects within a conductive layer of a semiconductor IC device. The C-PHY interface employs three-phase symbol encoding to transmit data symbols on 3-wire lanes, or “trios” where the signals transmitted on each trio include an embedded clock.

For the purposes of this disclosure, a symbol may refer to or define signaling state of the trio within a unit interval (UI), symbol transmission interval, or symbol interval, in which data is modulated or encoded in the waveforms transmitted over the trio. In one example, multiple bits of data may be encoded in a symbol that is to be transmitted over a trio in one UI. The terms “symbol interval”, “symbol transmission interval” and “UI” may be used interchangeably in reference to certain data communication links.

A symbol transmission interval may be defined as the interval of time in which a single three-phase symbol controls the signaling state of a trio. The C-PHY interface provides a three-phase encoding scheme that defines three phase states and two polarities, providing 6 states and 5 possible transitions from each signaling state. Each signaling state can be defined by a combination of voltage and/or current. A transition between signaling states is required after each symbol transmission interval. A receive clock signal may be generated based on the transitions that are guaranteed to occur between consecutive symbol transmission intervals. Data may be encoded in the type of transition that occurs between two symbol transmission intervals. The receive clock may be used to extract data from sequences of symbols.

A trio may be referred to as a lane herein. A multi-lane C-PHY communication channel may be established using multiple trios to carry data exchanged between a pair of devices, where each channel includes one trio that carries a portion of the data, which may be independently encoded in accordance with C-PHY protocols.

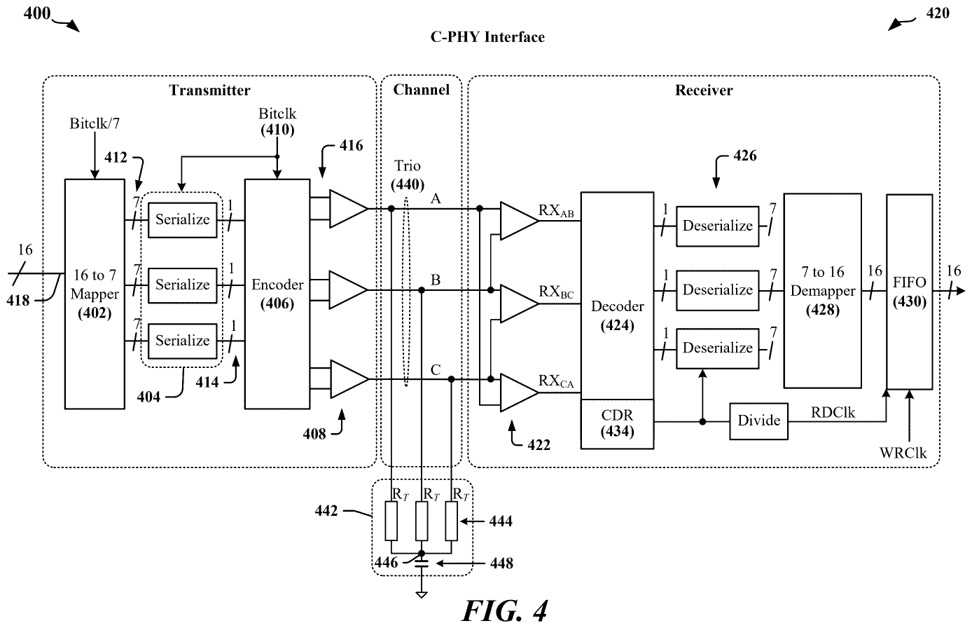

FIG. 4 illustrates an example of a system that employs a C-PHY interface. The illustrated example relates to a three-wire link configured to carry 3-phase polarity encoded differential signals. Differential signaling can effectively common mode rejection of electromagnetic interference. The use of 3-phase polarity encoding provides for high-speed data transfer and may consume half or less of the power of other interfaces at the desired operating frequency because fewer than 3 drivers are active at any time in a C-PHY link. The C-PHY interface uses 3-phase polarity encoding to encode multiple bits per symbol transition on the three-wire link. In one example, a combination of three-phase encoding and polarity encoding may be used to support a wide video graphics array (WVGA), 80 frames per second liquid crystal display driver IC without a frame buffer, delivering pixel data for display refresh at 810 Mbps over three or more wires. In other examples, a C-PHY interface may be configured to support transmission rates of 6 giga symbols per second, or more.

In the depicted C-PHY interface, three-phase polarity encoding is used to control signaling state of connectors, wires, traces and other interconnects that provide a channel for communication. In the illustrated example, a single unidirectional channel, or lane, is provided using a combination of three wires (the trio 440). A termination network 442 may be coupled to the trio 440 at the receiving end of the channel. In the illustrated example, the termination network 442 includes three termination resistors 444. Each of the termination resistors 444 couples a respective wire in the trio 440 to a common node 446 in the termination network 442. In some implementations, the common node 446 is further coupled to system ground through a capacitor 448. In other implementations, the common node 446 may be coupled to a rail of a power supply through the capacitor 448. The nominal resistance value (R_{T}) of the termination resistors 444 may be configured or selected to match the characteristic impedance of a wire in the trio 440. Certain specifications for the C-PHY interface define a nominal 50 Ohm (50Ω) characteristic impedance for each wire in the trio 440 and a nominal differential impedance of 100Ω for each pair of wires in the in the trio 440. The differential impedance may relate to a combination of two wires in the trio 440.

Each wire in the trio 440 may be undriven, driven positive, or driven negative in any symbol transmission interval. For the purposes of this disclosure, a symbol transmission interval corresponds to a period of time in which a unit of data can be encoded in the signaling state of the trio 440, and may correspond to the period of the bit clock 410 used to control timing of the output of the encoder 406 shown in FIG. 4. A symbol may refer to signaling state of the trio within a symbol transmission interval in which data is modulated or encoded using the waveform of a transmitted signal.

In some instances, an undriven signal wire of the trio 440 may be in a high-impedance state. In some instances, an undriven signal wire of the trio 440 may be driven or pulled to a voltage level that lies substantially halfway between the positive and negative voltage levels provided on driven signal wires. In some instances, an undriven signal wire of the trio 440 may have no current flowing through it. Drivers 408 in the C-PHY transmitter 400 coupled to the signal wires of the trio 440 are controlled such that only one wire of the trio 440 is in each of three states (denoted as +1, −1, or 0) in each symbol transmission interval.

In one example, the drivers 408 include unit-level current-mode drivers. In another example, the drivers 408 drive opposite polarity voltages on two signals transmitted on two signal wires of the trio 440 while the third signal wire is at high impedance and/or pulled to ground. For each transmitted symbol, at least one signal is in the undriven (0) state, while one signal is driven to the positive (+1 state) and one signal is driven to the negative (−1 state). Accordingly, the sum of current flowing to the C-PHY receiver 420 is nominally zero amperes. For each symbol, the state of at least one signal wire of the trio 440 is changed from the symbol transmitted in the preceding transmission interval.

In the C-PHY transmitter 400, a mapper 402 may receive a 16-bit input data word 418, and the mapper 402 may map the input data word 418 to a set of 7 symbols 412 for transmitting sequentially over the signal wires of the trio 440. A 3-phase polarity encoder 406 may receive the set of 7 symbols 412 produced by the mapper, one input symbol 414 at a time, and computes the state of each signal wire of the trio 440 for each symbol transmission interval, based on the immediately preceding state of the signal wires of the trio 440. The set of 7 symbols 412 may be serialized using parallel-to-serial converters 404, for example. The 3-phase polarity encoder 406 provides control signals 416 to define the outputs of the drivers 408. The 3-phase polarity encoder 406 selects the states of the signal wires of the trio 440 based on the input symbol 414 and the previous states of signal wires of the trio 440 and may provide control signals 416 to cause the drivers 408 to produce the desired signaling state on the trio 440.

The use of three-wire, three-phase encoding permits several bits to be encoded in a plurality of symbols where the bits per symbol is not an integer. In the example of a three-wire, three-phase system, there are 3 available combinations of 2 wires, which may be driven simultaneously, and 2 possible combinations of polarity on the simultaneously driven pair of wires, yielding 6 possible states. Since each transition occurs from a current state, 5 of the 6 states are available at every transition. With 5 states, log₂(5)≈2.32 bits may be encoded per symbol transition. Accordingly, a mapper may accept a 16-bit word and convert it to a 7-symbol sequence because 7 symbols carrying 2.32 bits per symbol can encode 16.24 bits. In other words, a combination of seven symbols that encodes five states has 5⁷ (78,125) permutations. Accordingly, the 7 symbols may be used to encode the 2¹⁶ (65,536) permutations of 16 bits.

In the illustrated example, the C-PHY receiver 420 includes differential receivers 422 (e.g., voltage comparators) that are configured to provide raw symbols (i.e.: the combination of RX_{AB}, RX_{BC} and RX_{CA}), which represent the state of each of three signal wires of the trio 440. A decoder 424 produces a decoded symbol that represents the change in the state of the three signal wires compared to the state transmitted in the previous symbol period. The decoder 424 includes or cooperates with a clock and data recovery (CDR) circuit 434 that may be configured to generate a receive clock signal from timing of transitions in the signaling state of the trio 440, and to use the clock signal to capture symbols representing signaling state of the trio 440 in sequential symbol transmission intervals. In one example, seven sequentially captured symbols may be assembled by serial-to-parallel convertors 426 and used to produce a set of 7 symbols to be processed by a demapper 428 to obtain 16 bits of data that may be buffered in a first-in-first-out (FIFO) storage device 430. In one example, the FIFO storage device 430 may be implemented using a set of registers.

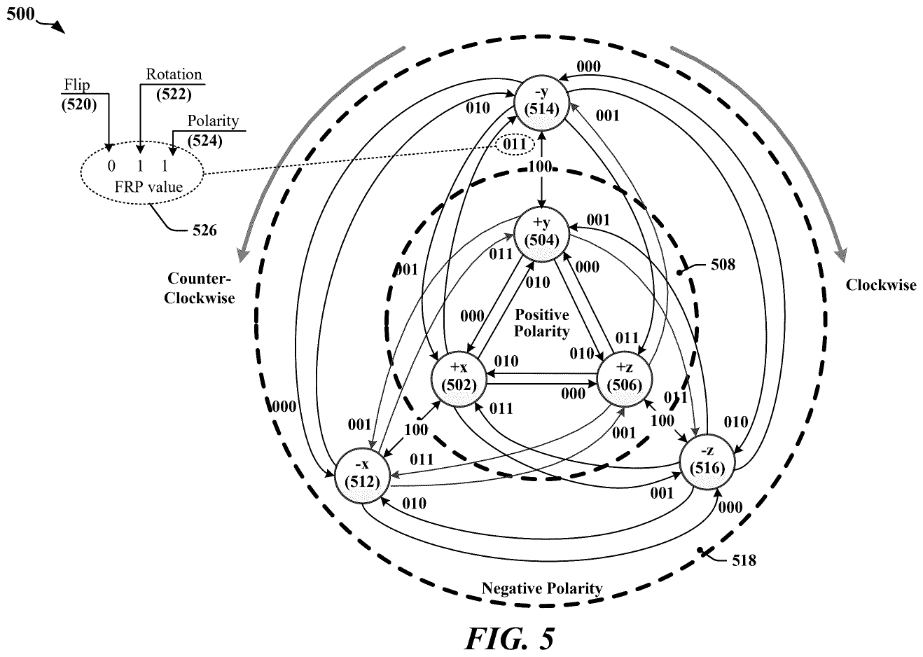

FIG. 5 is a state transition diagram 500 illustrating the possible signaling states 502, 504, 506, 512, 514, 516 of the three wires in a 3-wire, 3-phase MIPI Alliance C-PHY high-speed interface. All possible transitions from each signaling state 502, 504, 506, 512, 514, 516 are illustrated. The transitions in the state transition diagram 500 can be represented by a Flip, Rotate, Polarity (FRP) symbol 526. For every transition, the FRP symbol 526 has one of the values defined by the set of three-bit binary numbers: {000, 001, 010, 011, 100}. The Rotate bit 522 of the FRP symbol 526 indicates the direction of phase rotation associated with a transition to a next state. The Polarity bit 524 of the FRP symbol 526 is set to binary 1 when a transition to a next state involves a change in polarity. When the Flip bit 520 of the FRP symbol 526 is set to binary 1, the Rotate and Polarity values may be ignored and/or zeroed. A flip represents a state transition that involves only a change in polarity. Accordingly, the phase of a 3-phase signal is not considered to be rotating when a flip occurs and the polarity bit is redundant when a flip occurs. The FRP symbol 526 corresponds to wire state changes for each transition. The state transition diagram 500 may be separated into an inner circle 508 that includes the positive polarity signaling states 502, 504, 506 and an outer circle 518 that encompasses the negative polarity signaling states 512, 514, 516.

According to a data-encoding scheme corresponding to the state transition diagram 500, the phase of a 3-phase signal may rotate in two directions and may be transmitted on each connector of a trio. In FIG. 4, for example, the trio 440 includes wires and/or connectors A, B, and C. Each of the three signals is independently driven on respective wires of the trio 440. Each of the three signals includes a version of the 3-phase signal, with each signal being 120 degrees out of phase relative to the other two signals. At any point in time, each wire of the trio 440 is in a different one of the states {+1, 0, −1}. At any point in time, each wire of the trio 440 is in a different state than the other two wires. The illustrated encoding scheme can also encode information in the polarity and/or changes of polarity of the two wires that are actively driven to the +1 and −1 states. Information may also be encoded in the polarity and/or changes of polarity of signaling state of the driven wires.

In the illustrated example, one bit of data may be encoded in the phase rotation, or phase change in the 3-wire, 3-phase link, and an additional bit may be encoded in the polarity or changes in polarity of two driven wires. In certain embodiments, more than two bits can be encoded in each transition of a 3-wire, 3-phase encoding system by allowing transition to any of the possible states from a current state. Given three rotational phases and two polarities for each phase, 6 states are defined, such that 5 states are available from any current state. Accordingly, there may be log₂(5)≈2.32 binary data bits encoded per transition and the mapper may convert 16-bit words to 7 symbol sequences.

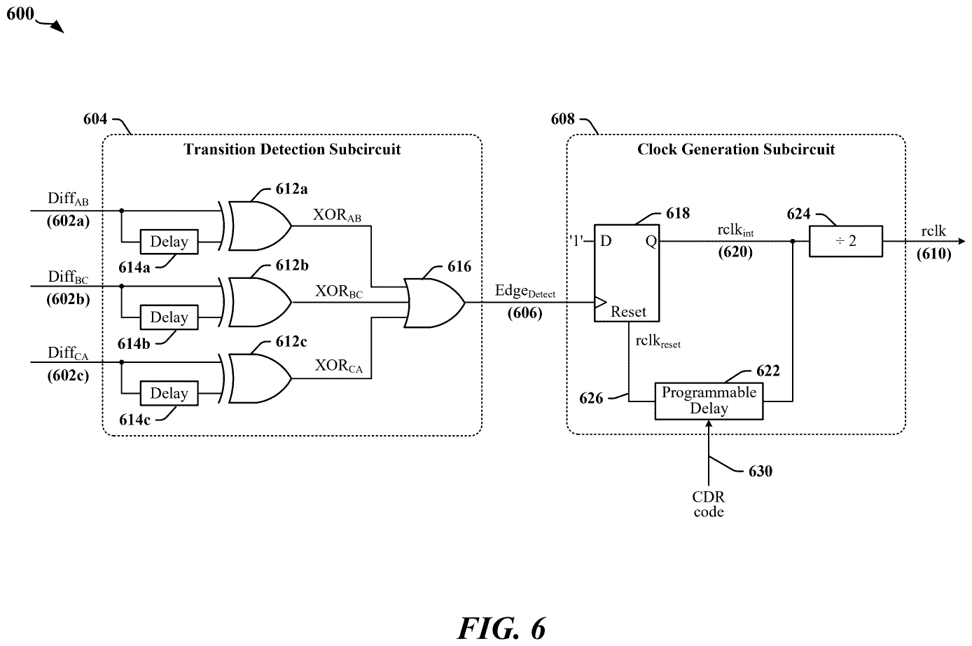

FIG. 6 illustrates an example of a clock recovery circuit 600 that may be implemented in a CDR of a C-PHY receiver. In one example, the clock recovery circuit 600 may be implemented in the CDR circuit 434 illustrated in FIG. 4. The clock recovery circuit 600 includes a transition detection subcircuit 604 and a clock generation subcircuit 608. The transition detection subcircuit 604 receives three difference signals 602a, 602b, 602c. Each of the difference signals 602a, 602b, 602c represents the difference in signaling state between two of three wires or connectors in a C-PHY communication link (e.g., the trio 440 shown in FIG. 4) and all three combinations of two wires is represented by the difference signals 602a, 602b, 602c. In certain implementations, the difference signals 602a, 602b, 602c are produced by digital comparators, which may correspond to the differential receivers 422 shown in FIG. 4. The digital comparators may provide a binary output indicating which of its inputs has a greater voltage. Each digital comparator may be characterized as indicating relative polarity of its inputs. Zero crossings of the outputs of the digital comparators can be used to indicate the location of a symbol transmission interval.

In the illustrated example, the transition detection subcircuit 604 includes a set of exclusive-OR gates 612a, 612b, 612c. Each of the difference signals 602a, 602b, 602c is coupled to a first input of one of the exclusive-OR gates 612a, 612b, 612c and to a corresponding delay circuit 614a, 614b, 614c that has an output that drives the other input of the associated exclusive-OR gate 612a, 612b, 612c. Each delay circuit 614a, 614b, 614c is configured to provide a delay that is a fraction of the transmission interval associated with each symbol transmitted over the C-PHY communication link. In some instances, each of the delay circuits 614a, 614b, 614c is implemented using two or more inverters. The output of an exclusive-OR gate 612a, 612b, 612c is normally at logic ‘0’ and transitions to logic ‘1’ when signaling state of the associated difference signal 602a, 602b, 602c changes. The output of an exclusive-OR gate 612a, 612b, 612c returns to logic ‘0’ when the changed signaling state of the associated difference signal 602a, 602b, 602c propagates through the corresponding delay circuit 614a, 614b, 614c. Accordingly, each change in signaling state of a difference signal 602a, 602b, 602c generates a pulse in the output of a corresponding exclusive-OR gate 612a, 612b, 612c.

In the illustrated example, the outputs of the exclusive-OR gates 612a, 612b, 612c are received by an OR gate 616. The output of the OR gate 616 is normally at logic ‘0’ and transitions to logic ‘1’ when an output of any of the exclusive-OR gates 612a, 612b, 612c is in the logic ‘1’ state. In this example, the pulses generated by the exclusive-OR gates 612a, 612b, 612c are propagated through the OR gate 616. Multiple pulses or a variable length pulse may be produced in the output of the OR gate 616 at certain transitions between symbol transmission intervals due to timing differences associated with multiple transitions in multiple difference signals 602a, 602b, 602c.

In the illustrated example, the output 606 of the transition detection subcircuit 604 is driven by the OR gate 616. The output 606 of the transition detection subcircuit 604 is provided to a clock input of a flipflop 618 in the clock generation subcircuit 608. The output of the flipflop 618 provides an intermediate receive clock signal (i.e., the rclkᵢₙₜ signal 620). The rclkᵢₙₜ signal 620 is expected to be at logic ‘0’ when a pulse is provided to the clock input, due to the operation of a reset signal 626 coupled to the reset input of the flipflop 618. The reset signal 626 is a delayed version of the rclkᵢₙₜ signal 620, and the reset signal 626 resets the flipflop 618 when it transitions to the logic ‘1’ state.

In the illustrated example, rising edges at the clock input of a flipflop 618 cause a logic ‘1’ state to be propagated through the flipflop 618 to the rclkᵢₙₜ signal 620. Multiple rising edges that can occur at the clock input of a flipflop 618 have no effect on the rclkᵢₙₜ signal 620 before the reset signal 626 clears the output of the flipflop 618. The configuration of the clock generation subcircuit 608 effectively masks all rising edges in the output 606 of the transition detection subcircuit 604 that occur after the first rising edge and before the flipflop 618 is reset.

The rclkᵢₙₜ signal 620 is provided to a programmable delay circuit 622 that outputs the reset signal 626. The duration of the delay introduced by the programmable delay circuit 622 may be configured to ensure that a falling edge in the rclkᵢₙₜ signal 620 occurs in every symbol transmission interval. In some implementations, the programmable delay circuit 622 may be configured to provide the rclkᵢₙₜ signal 620 with a duty cycle that lies within tolerances defined or configured for the rclkᵢₙₜ signal 620. In some implementations, the programmable delay circuit 622 may be configured to position the falling edge of the rclkᵢₙₜ signal 620 within the symbol transmission interval. The flipflop 618 is reset when the logic ‘1’ state that is propagated through the flipflop 618 to the rclkᵢₙₜ signal 620 is propagated through the programmable delay circuit 622 to the reset signal 626.

The rclkᵢₙₜ signal 620 may be provided to a divider circuit 624 that produces a receive clock signal (i.e., the rclk signal 610) as an output of the clock recovery circuit 600. In the illustrated example, the divider circuit 624 outputs the rclk signal 610 at a frequency that is half the frequency of the rclkᵢₙₜ signal 620. The divider circuit 624 in this example may be implemented using a flipflop or a counter. In other examples, the divider circuit 624 may be implemented using a string of flipflops or a counter and can provide clock signals at multiple frequencies.

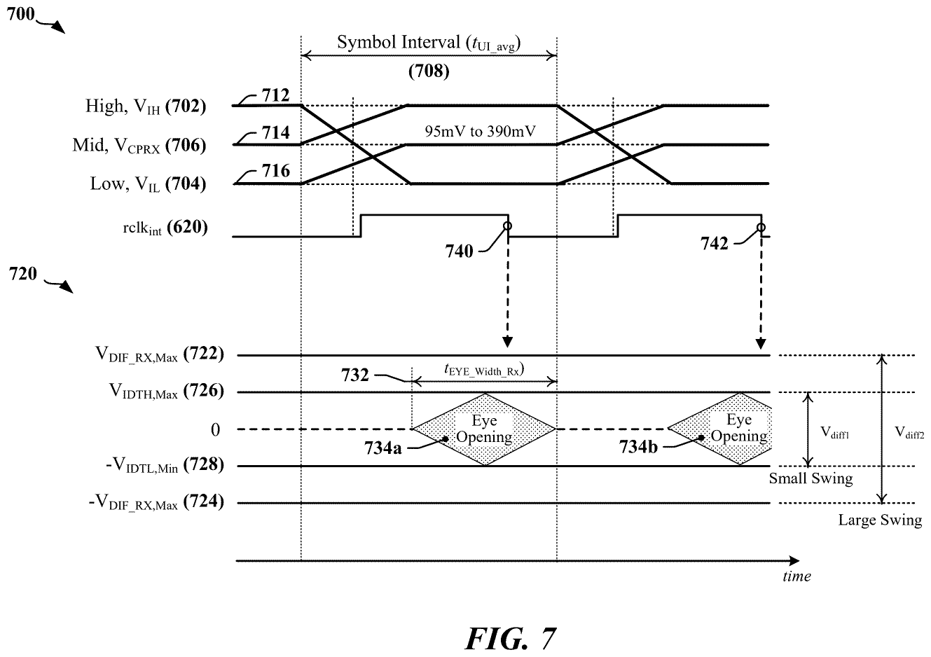

FIG. 7 illustrates certain aspects of the timing associated with the clock recovery circuit 600 illustrated in FIG. 6. The timing diagram 700 shows three signals 712, 714, 716 transitioning between three defined signaling states 702, 704, 706. The high signaling state 702 has a voltage level identified as V_{IH}, the low signaling state 704 for high-speed operation has a voltage level identified as V_{IL}, and the mid-level or common mode signaling state 706 has a voltage level identified as V_{CPRX}. In C-PHY specifications for CSI, the common mode voltage for a receiver defined for receiver ranges from 95 mV<V_{CPRX}<390 mV to account for any common mode voltage range shifting, termination mismatch or sensor variations.

The eye diagram 720 shows eye openings 734a, 734b that correspond to the interval of time in which signaling state of the three signals 712, 714, 716 can be reliably sampled under all expected operating conditions. In one example, the eye opening 734a has a width 732 and a voltage range in which the three signals 712, 714, 716 can be sampled.

The eye diagram 720 also shows the possible output states of analog differential receivers. A maximum positive difference state 722 has a largest voltage level identified as V_{DIF_RX_Max}, a maximum negative difference state 724 has a largest voltage level identified as −V_{DIF_RX_Max}, an intermediate positive difference state 726 has a largest voltage level identified as V_{IDTH_Max}, an intermediate negative difference state 728 has a largest voltage level identified as −V_{IDTH_Max}, The amplitude of the largest expected voltage swing at the beginning of a symbol transmission interval 708 is and 2V_{DIF_RX_Max} and the amplitude of the smallest expected voltage swing at the beginning of a symbol transmission interval 708 is and 2V_{IDTH_Max}.

In the illustrated example, the points in time at which the three signals 712, 714, 716 can be sampled are determined by falling edges 740, 742 in the rclkᵢₙₜ signal 620. As discussed in relation to FIG. 6, the rclkᵢₙₜ signal 620, rising edges in the rclkᵢₙₜ signal 620 occur when the clock input of a flipflop 618 is triggered by pulses in the output 606 of the transition detection subcircuit 604. The falling edges 740, 742 in the rclkᵢₙₜ signal 620 occur when the rising edges in the rclkᵢₙₜ signal 620 propagate through the programmable delay circuit 622.

The programmable delay circuit 622 may be configured to provide a delay that aligns the falling edges 740, 742 in the rclkᵢₙₜ signal 620 with a desired or specified sampling point within the corresponding symbol transmission intervals and, more particularly, within the eye openings 734a, 734b of the corresponding symbol transmission intervals. In the illustrated example, the programmable delay circuit 622 may be configured using a digital signal 630 that provides a CDR code. The CDR code may define the duration of the delay between edges in the rclkᵢₙₜ signal 620 and corresponding edges in the reset signal 626 coupled to the reset input of the flipflop 618.

The clock recovery circuit 600 illustrated in FIG. 6 recovers the clock by providing a first type of edge (e.g., a transition from low-to-high logic states) in response to the first zero crossing in difference signals 602a, 602b, 602c at a symbol transmission interval boundary, and by providing a second type of edge (e.g., a transition from high-to-low logic states) when an edge of the first type propagates through a delay circuit. Multiple zero crossings that occur in the difference signals 602a, 602b, 602c at the symbol transmission interval boundary are accommodated by masking second or later zero crossings at each symbol transmission interval boundary. Multiple zero crossings may be regarded or treated as timing jitter. The programmable delay circuit 622 may be configured according to the rule that:

jitter<loop delay<1UI,

where loop delay includes the sum of the delays introduced by the programmable delay circuit 622, the flipflop 618 and any intervening logic circuits.

Receiver jitter and the calibrated CDR code used to configure the programmable delay circuit 622 may vary based on a variety of parameters. In one example, jitter may vary with variations in manufacturing process, circuit supply voltage, and die temperature (PVT). The CDR code used to configure the programmable delay circuit 622 may be selected based on analog front-end settings (e.g., configuration of physical layer circuits), expected operating conditions and application needs (e.g., signaling frequency, error rate tolerances, etc.). Typically, the CDR code in conventional CDRs cannot be adjusted once established and may be defined to accommodate the effects of expected worst case variations in operating conditions attributable to PVT. That is to say, the conventional CDR code is typically optimized for PVT corners or expected worst-case operating conditions. For the purposes of this disclosure, PVT corners represent limits of process, voltage, or temperature and/or combinations thereof. PVT corners may be correlated with limits of operational characteristics of a circuit, including current, voltage, temperature, switching frequency, rise time, fall time, settling time and other characteristics. It is challenging to identify a fixed set of CDR code values that can function effectively across different conditions.

Evolving specification for C-PHY interfaces provide for ever-increasing symbol transmission rates, and the difficulty in defining CDR code values that remain effective under expected operating conditions increases accordingly. For example, the width 732 of the eye opening 734a in a 6 giga symbols per second (6 Gsps) C-PHY interface provides small timing margins that require greater precision in programmable delay circuit 622 operation when predefined CDR code values are to be used. CDR code values determined under laboratory conditions may be ineffective when millions of devices are produced and operated subject to differing PVT corners. Specifications and conventional systems typically do not include real time monitoring or boot-up calibration to dynamically adjust the CDR code for each part under changing PVT conditions.

Certain aspects of this disclosure provide dynamic calibration circuits and techniques that can support advanced process nodes with increasing data rate frequencies. In some implementations, the eye-opening associated with a C-PHY communication link can be determined and monitored in real-time. For example, the width 732 of the eye openings 734a, 734b illustrated in FIG. 7 may be determined and monitored. Monitoring the state of the eye-opening can enable dynamic calibration and provide metrics that can be used by a controller to configure communication link operation.

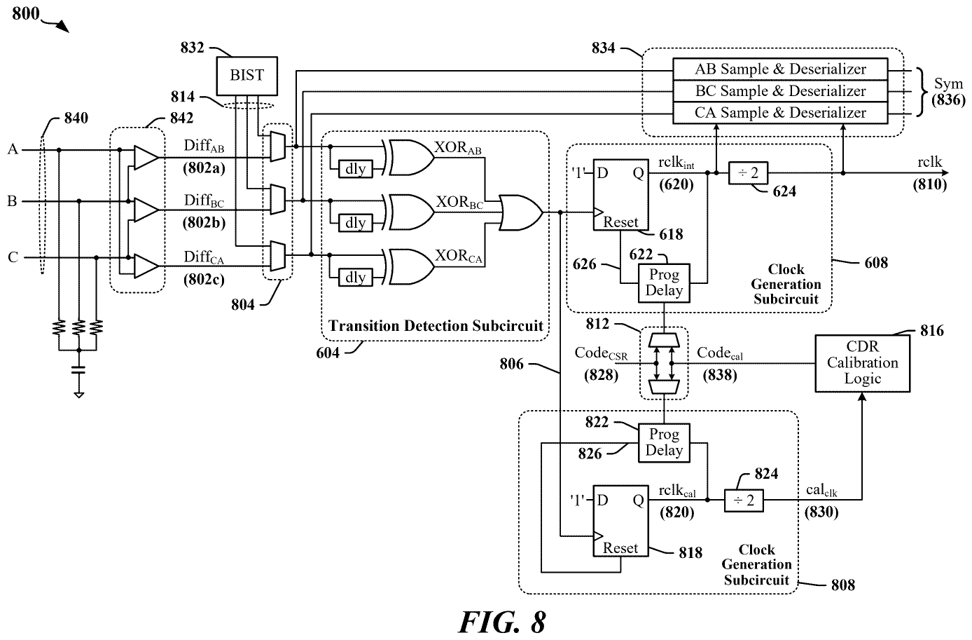

FIG. 8 illustrates an example of a CDR 800 that may be implemented, configured or dynamically calibrated in accordance with certain aspects of this disclosure. In one example, the CDR 800 may replace or be incorporated in CDR circuits such as the CDR circuit 434 illustrated in FIG. 4. The CDR 800 may correspond in some respects to the clock recovery circuit 600 illustrated in FIG. 6. For example, and for the purposes of this disclosure only, the illustrated CDR 800 incorporates the symbol transition detection subcircuit 604 and clock generation subcircuit 608 described in relation to FIG. 6. The illustrated CDR 800 includes sampling and deserialization circuits 834 that receive difference signals output by multiplexers 804 and use timing provided by the clock generation subcircuit 608 to produce sequences of symbols 836 representative of data encoded in the received difference signals.

A dummy CDR, or a duplicated portion of the CDR may be used to calibrate the receive clock signals used to capture and decode symbol information from the signals transmitted over a C-PHY communication link. In the illustrated example, CDR 800 includes a duplicate clock generation subcircuit 808. The duplicate clock generation subcircuit 808 may be a replica of the clock generation subcircuit 608, whereby the duplicate clock generation subcircuit 808 includes the same type and combination of gates and circuits as the clock generation subcircuit 608. In some implementations, sections or components of the duplicate clock generation subcircuit 808 are located in close proximity on the same semiconductor die as corresponding sections or components of the clock generation subcircuit 608. Elements of the clock generation subcircuits 608, 808 that are proximately located can be expected to be affected more or less equally by PVT variations.

In the illustrated CDR 800, the duplicate clock generation subcircuit 808 can operate in parallel with the clock generation subcircuit 608. The clock generation subcircuit 608 may be used in modes of operation (i.e., “mission mode”) in which the CDR 800 is used to generate clock signals and decode data transmitted over the C-PHY communication link. The input conditions for the duplicate clock generation subcircuit 808 are designed to be identical to the input conditions for the clock generation subcircuit 608.

The illustrated CDR 800 includes a CDR calibration logic circuit 816 that may be operated continuously. The CDR calibration logic circuit 816 may be implemented using a processing circuit that includes, for example, a processor, a finite state machine (FSM), a microcontroller or another type of controller. The processing circuit may be configured using a combination of control parameters and/or coded instructions, for example. The CDR calibration logic circuit 816 may be configured to monitor the outputs of the duplicate clock generation subcircuit 808 and clock generation subcircuit 608. The CDR calibration logic circuit 816 may respond to differences or changes in the output of the duplicate clock generation subcircuit 808 and/or the output of the clock generation subcircuit 608 by updating the CDR code used to control delays provided by the programmable delay circuit 622 in the clock generation subcircuit 608.

The input to the transition detection subcircuit 604 is controlled by the multiplexers 804. The multiplexers 804 may be controlled by a processing circuit that includes a processor, FSM, microcontroller or other controller based on a mode of operation of the CDR 800. In a normal, or mission mode of operation, the transition detection subcircuit 604 receives three difference signals 802a, 802b, 802c from a set of differential receivers 842. Each differential receiver 842 may be implemented using a comparator that provides a digital output representative of the difference between two input signals. Each of the differential receivers 842 may be configured to compare the signaling state of two wires in a trio 840 by subtraction (viz: A-B, B-C or C-A), when the wires of the trio 840 are identified as the set of wires {A, B, C}. All three combinations of two wires can be represented by the difference signals 802a, 802b, 802c. A zero crossing of signaling state in any of the difference signals 802a, 802b, 802c may indicate the beginning of a symbol transmission interval.

The transition detection subcircuit 604 shown in FIG. 8 may correspond to and/or function substantially as described in relation to the transition detection subcircuit 604 shown in FIG. 6. In relation to FIG. 8, it is sufficient to note that the transition detection subcircuit 604 generates a pulse in its output 806 in response to a first-occurring zero crossing of signaling state in the difference signals 802a, 802b, 802c. Multiple pulses or a variable length pulse may be produced in the output 806 of the transition detection subcircuit 604 when multiple transitions occur at the beginning of a symbol transmission interval, and when zero crossings occur at different times.

In the illustrated example, the output 806 of the transition detection subcircuit 604 is provided to a clock input of the flipflop 618 in the clock generation subcircuit 608. The output of the flipflop 618 provides an intermediate receive clock signal (i.e., the rclkᵢₙₜ signal 620). The rclkᵢₙₜ signal 620 is expected to be at logic ‘0’ when a pulse is provided to the clock input, due to the action of a reset signal 626 coupled to the reset input of the flipflop 618. The reset signal 626 is a delayed version of the rclkᵢₙₜ signal 620 that resets the flipflop 618 when in the logic ‘1’ state.

In the illustrated example, rising edges at the clock input of a flipflop 618 cause a logic ‘1’ state to be propagated through the flipflop 618 to the rclkᵢₙₜ signal 620. Multiple rising edges that may occur at the clock input of a flipflop 618 before the reset signal 626 clears the output of the flipflop 618 have no effect on the rclkᵢₙₜ signal 620. The configuration of the clock generation subcircuit 608 effectively masks all rising edges in the output 606 of the transition detection subcircuit 604 that occur after the first zero crossing of signaling state in any of the difference signals 802a, 802b, 802c and before the flipflop 618 is reset.

The rclkᵢₙₜ signal 620 is provided to a programmable delay circuit 622 that outputs the reset signal 626. The duration of the delay introduced by the programmable delay circuit 622 may be configured to ensure that a falling edge in the rclkᵢₙₜ signal 620 occurs in every symbol transmission interval. In some implementations, the programmable delay circuit 622 may be configured to provide the rclkᵢₙₜ signal 620 with a duty cycle falls within tolerances defined or configured for the rclkᵢₙₜ signal 620. In some implementations, the programmable delay circuit 622 may be configured to position the falling edge of the rclkᵢₙₜ signal 620 within the symbol transmission interval. The flipflop 618 is reset when the logic ‘1’ state that is propagated through the flipflop 818 to the rclkᵢₙₜ signal 620 is propagated through the programmable delay circuit 622 to provide the reset signal 626.

The rclkᵢₙₜ signal 620 may be provided to a divider circuit 624 that produces a receive clock signal (i.e., the rclk signal 810) as an output of the CDR 800. In the illustrated example, the divider circuit 624 outputs the rclk signal 810 at a frequency that is half the frequency of the rclkᵢₙₜ signal 620. The divider circuit 624 in this example may be implemented using a flipflop or counter. In other examples, the divider circuit 624 may be implemented using a string of flipflops or a counter that can provide clock signals at multiple frequencies.

According to certain aspects of this disclosure, a codeword (i.e., the CDR_{CSR} code 828) used to configure the delay provided by the programmable delay circuit 622 may be calibrated using the duplicate clock generation subcircuit 808. The CDR_{CSR} code 828 can be used to configure the delay provided by the programmable delay circuit 622 such that sampling edges in the rclkᵢₙₜ signal 620 coincide with a desired or specified sampling point within the corresponding symbol transmission intervals. In one example, the sampling edges control timing at which a flipflop or register captures signaling state of the difference signals 802a, 802b, 802c. The CDR 800 may be calibrated to cause the sampling edges to occur at an optimal time within the corresponding symbol transmission intervals. In certain implementations, the CDR_{CSR} code 828 may be encoded using binary or unary encoding. Unary encoding represents data in the quantity of bits set to ‘1’ that precede a terminating ‘0’, or the quantity of bits set to ‘0’ that precede a terminating ‘1’. Unary encoding may also be referred to as thermometer encoding. The CDR_{CSR} code 828 may define the duration of the delay between edges in the rclkᵢₙₜ signal 620 and corresponding edges in the reset signal 626 coupled to the reset input of the flipflop 618.

The duplicate clock generation subcircuit 808 may be configured to respond to inputs in substantially the same way as the clock generation subcircuit 608 shown in FIG. 8. In the illustrated example, the output 806 of the transition detection subcircuit 604 is provided to a clock input of the flipflop 818 in the duplicate clock generation subcircuit 808. The output of the flipflop 818 provides a calibration receive clock signal (i.e., the rclk_{cal} signal 820). The rclk_{cal} signal 820 is expected to be at logic ‘0’ when a pulse is provided to the clock input, due to the action of a reset signal 826 coupled to the reset input of the flipflop 818. The reset signal 826 is a delayed version of the rclk_{cal} signal 820 that resets the flipflop 818 when in the logic ‘1’ state.

In the illustrated example, rising edges at the clock input of a flipflop 818 cause a logic ‘1’ state to be propagated through the flipflop 818 to the rclk_{cal} signal 820. Multiple rising edges that may occur at the clock input of a flipflop 818 before the reset signal 826 clears the output of the flipflop 818 have no effect on the rclk_{cal} signal 820. The configuration of the duplicate clock generation subcircuit 808 effectively masks all rising edges in the output 606 of the transition detection subcircuit 604 that occur after the first zero crossing of signaling state in any of the difference signals 802a, 802b, 802c and before the flipflop 818 is reset.

The rclk_{cal} signal 820 may be provided to a divider circuit 824 that produces a calibration clock signal (i.e., the cal_{clk} signal 830) as an output of the duplicate clock generation subcircuit 808. In the illustrated example, the divider circuit 824 outputs the cal_{clk} signal 830 at a frequency that is half the frequency of the rclk_{cal} signal 820. The divider circuit 824 in this example may be implemented using a flipflop or counter. In other examples, the divider circuit 824 may be implemented using a string of flipflops or a counter that can provide clock signals at multiple frequencies.

In certain implementations, the rclk_{cal} signal 820 is provided to a programmable delay circuit 822 that outputs the reset signal 826. The duration of the delay introduced by the programmable delay circuit 822 can be configured to ensure that a falling edge in the rclk_{cal} signal 820 occurs in every symbol transmission interval. In some implementations, the programmable delay circuit 822 can be configured to provide the rclk_{cal} signal 820 with a duty cycle falls within tolerances defined or configured for the rclk_{cal} signal 820. In some implementations, the programmable delay circuit 822 can be configured to position the falling edge of the rclk_{cal} signal 820 within the symbol transmission interval. The flipflop 818 is reset when the logic ‘1’ state that is propagated through the flipflop 818 to the rclk_{cal} signal 820 is propagated through the programmable delay circuit 822 to provide the reset signal 826.

In certain implementations, the cal_{clk} signal 830 is provided to the CDR calibration logic circuit 816. In these implementations, the CDR calibration logic circuit 816 may also receive the rclk signal 810 output by the clock generation subcircuit 608. In certain implementations, the rclk_{cal} signal 820 is provided to the CDR calibration logic circuit 816. In these implementations, the CDR calibration logic circuit 816 may also receive the rclkᵢₙₜ signal 620 generated by the clock generation subcircuit 608.

According to certain aspects of this disclosure, the clock generation subcircuit 808 may generate a calibration codeword (i.e., the CDR_{cal} code 838) that may be used to configure the delay provided by the programmable delay circuit 822 during calibration modes of operation. In certain implementations, the CDR_{cal} code 838 may be encoded using binary or unary encoding. In some calibration modes of operation, the CDR_{cal} code 838 may also be provided to the programmable delay circuit 622 in the “mission” clock generation subcircuit 608. A multiplexing circuit 812 may be provided to determine which CDR code is provided to the generation subcircuit 608 and to the duplicate clock generation subcircuit 808. In one example, the multiplexing circuit 812 is controlled by the CDR calibration logic circuit 816.

The CDR 800 may be calibrated during system initialization or configuration. In some implementations, a calibration process may be controlled or monitored by built-in self-test (BIST) circuits, which are depicted in FIG. 8 as BIST 832. In the illustrated example, BIST 832 may be configured to generate or otherwise provide C-PHY encoded signals 814 in an initial calibration mode. The multiplexers 804 may be configured to couple the C-PHY encoded signals 814 in the initial calibration mode. The CDR calibration logic circuit 816 may perform a sweep of possible or available values for the CDR_{cal} code 838 to determine an optimal delay setting for the programmable delay circuit 822 in the duplicate clock generation subcircuit 808, which may subsequently be used to configure the programmable delay circuit 622 in the mission clock generation subcircuit 608. In some implementations, the optimal delay setting for the programmable delay circuit 622 in the “mission” clock generation subcircuit 608 ensures that the data encoded in the C-PHY encoded signals 814 can be accurately decoded. In some implementations, the initial calibration mode may be used to sweep the possible or available values for the CDR_{CSR} code 828.

The delay provided by the programmable delay circuit 622 determines the loop frequency for the loop that comprises the flipflop 618 and the programmable delay circuit 622, and the delay provided by the programmable delay circuit 822 determines the loop frequency for the loop that comprises the flipflop 818 and the programmable delay circuit 822. Sweeping the possible or available values for the CDR_{cal} code 838 and/or for the CDR_{CSR} code 828 may incrementally modify the respective loop frequencies. In some implementations, the loop frequency of the programmable delay circuit 622 may be calibrated to match the as closely as possible the frequency of the clock signal embedded in the C-PHY encoded signals that are received over the trio 840. An exact match is typically not essential, since the frequency of the rclkᵢₙₜ signal 620 follows the frequency of the embedded clock signal in normal operation.

In normal or mission modes of operation, the rclkᵢₙₜ signal 620 is generated based on a sequence of pulses output by the transition detection subcircuit 604. Each cycle of the rclkᵢₙₜ signal 620 begins at the first-occurring zero crossing of signaling state in the difference signals 802a, 802b, 802c in a first transmitted symbol transmission interval. Each cycle of the rclkᵢₙₜ signal 620 ends at the first-occurring zero crossing of signaling state in the difference signals 802a, 802b, 802c at the next transmitted symbol transmission interval. The average frequency of the rclkᵢₙₜ signal 620 corresponds closely to the frequency of the embedded clock signal, even when the loop frequency of the programmable delay circuits 822 does not precisely match the frequency of the embedded clock signal. Differences between the loop frequency of the programmable delay circuits 822 and the frequency of the embedded clock can be expected to modify the duty cycle of the rclkᵢₙₜ signal 620. In some instances, a duty cycle of greater or less than 50% may be desired in order to optimally position a sampling edge derived from the rclkᵢₙₜ signal 620 within the eye opening associated with the C-PHY encoded signals that rare received over the trio 840s (see the eye openings 734a, 734b, for example).

Calibration performed during system initialization or configuration may configure the clock generation subcircuit 608 to have a loop frequency that lies within a range of acceptable frequencies. The loop frequency of the mission clock generation subcircuit 608 can be expected to track the frequency of the clock signal embedded in C-PHY encoded signals unless the programmable delay circuit 622 fails to suppress additional transition detection at the beginning of a symbol transmission interval or improperly suppresses transitions at the beginning of the immediately following symbol transmission interval. Failure to suppress additional transitions at the beginning of a symbol transmission interval can be attributed to a programmable delay circuit 622 that provides a delay that is too short and can result in the mission clock generation subcircuit 608, and can produce too many pulses in the rclkᵢₙₜ signal 620 that increase the apparent or average frequency of the rclk signal 810. The suppression of transitions at the beginning of the immediately following symbol transmission interval can be attributed to a programmable delay circuit 622 that provides a delay that is too long and can result in the mission clock generation subcircuit 608 producing too few pulses in the rclkᵢₙₜ signal 620 and thereby reduce the apparent or average frequency of the rclk signal 810.

Symbol errors can occur when the loop frequency is too high or too low due to missed or invalid symbol transmission intervals and/or transitions between missed or invalid symbol transmission intervals. Symbol errors may be detected by C-PHY physical layer circuits during link synchronization preceding data transmissions. A high bit error rate (BER) indicated, identified or detected by higher layer C-PHY modules may be associated with a loop frequency that does not sufficiently match the frequency of the clock signal embedded in C-PHY encoded signals.

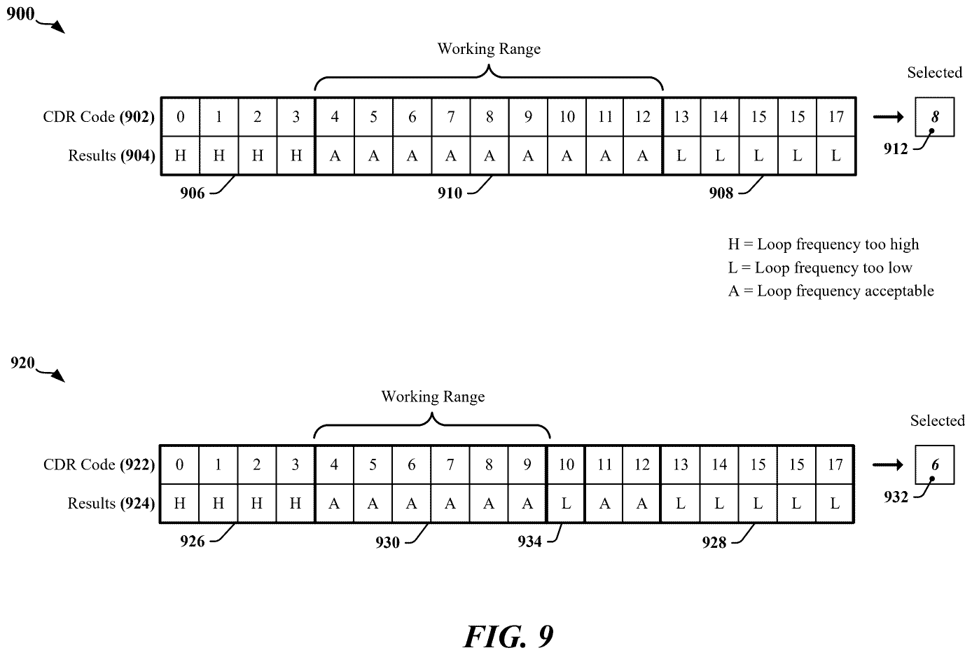

FIG. 9 illustrates certain aspects of a CDR code calibration procedure that may be implemented in accordance with certain aspects of this disclosure. The results 904, 924 shown in the tables 900, 920 relate CDR code values to loop frequency, and more particularly to an indication of whether loop frequency is too high, too low, or within an acceptable range. The CDR code calibration procedure may be used to calibrate CDR_{cal} code 838 and/or CDR_{CSR} code 828 during system initialization, and may be used to recalibrate the CDR_{cal} code 838 during normal modes of operation, whereby a recalibrated CDR_{cal} code 838 can be used as the CDR_{CSR} code 828 upon completion of recalibration.

The results of two CDR code calibration sweeps are tabulated. In the first table 900, a sweep commences with a test performed when the CDR code 902 is set to a minimum value, and continues with additional tests after the CDR code 902 is incrementally increased until a maximum code value has been tested. In the first table 900, the value of the CDR code 902 may be calculated as some preconfigured minimum value with an integer multiple of incremental code value increases added for each test. In the illustrated example, up to 17 increments can be applied. The results 904 illustrated by the first table 900 correspond to a configuration of the CDR 800 in which each value in a first range of values 906 for the CDR code 902 produces a loop frequency that is too high, each value in a second range of values 908 for the CDR code 902 produces a loop frequency that is too low, and each value in a third range of values 910 for the CDR code 902 produces an acceptable or workable loop frequency. In some implementations, a value 912 that lies near the middle of the third range of values 910 for the CDR code 902 is selected and used to configure the mission clock generation subcircuit 608 for normal modes of operation.

In the second table 920, a sweep commences with a test performed when the CDR code 922 is set to a minimum value, and continues with additional tests after the CDR code 922 is incrementally increased until a maximum code value has been tested. In the second table 920, the value of the CDR code 922 may be calculated as some preconfigured minimum value with an integer multiple of incremental code value increases added for each test. In the illustrated example, up to 17 increments can be applied. The results 924 illustrated by the second table 920 correspond to a configuration of the CDR 800 in which each value in a first range of values 926 for the CDR code 922 produces a loop frequency that is too high, each value in a second range of values 928 for the CDR code 922 produces a loop frequency that is too low, and each value in a third range of values 930 for the CDR code 922 produces an acceptable or workable loop frequency. In some implementations, a value 932 that lies near the middle of the third range of values 930 for the CDR code 922 is selected and used to configure the mission clock generation subcircuit 608 for normal modes of operation.

The second table 920 also reflects the effect of a jitter that may be caused by a combination of a slow first-occurring zero crossings of signaling state in the difference signals 802a, 802b, 802c at the beginning of one symbol transmission interval and a fast first-occurring zero crossings of signaling state in the immediately-following symbol transmission interval. In this context, a code value 934 that produces a loop frequency that is acceptable on average may be considered to be too slow dur to occasional or lower probability edge timing. In this example, the eye-opening associated with a C-PHY communication link is effectively shrunk in size and this is reflected in the smaller range of values 930 that produce an acceptable loop frequency.

According to one aspect of this disclosure, CDR 800 may be configured to monitor the eye-opening associated with a C-PHY communication link. A duplicate clock generation subcircuit 808 provided in accordance with certain aspects of this disclosure can be configured to continuously sweep the possible or available values for the CDR_{cal} code 838 to determine the bounds of an eye-opening corresponding to the C-PHY encoded signals received over the trio 840. In one example, the CDR calibration logic circuit 816 may be configured to compare the frequency of the cal_{clk} signal 830 with the frequency of the rclk signal 810. The comparison may be performed using counters and/or one or more digital comparators, for example. In one implementation, a first counter clocked by the rclk signal 810 is expected to have the same count value as a second counter that is clocked by the cal_{clk} signal 830 when the frequency of the cal_{clk} signal 830 matches the frequency of the rclk signal 810 after a given number of clock cycles. An acceptable match may be determined by masking a certain number of least significant bits of the counter outputs. At the beginning of a sweep, the programmable delay circuit 822 may be configured with a minimum CDR code value that is expected to produce a delay that is too short and a loop frequency that is too high.

The programmable delay circuit 822 may be configured with incrementally increasing CDR code values until the frequency of the cal_{clk} signal 830 matches the frequency of the rclk signal 810. The CDR code value when the frequencies of the cal_{clk} signal 830 and the rclk signal 810 first match may be identified or associated with a first boundary of the eye-opening. The sweep continues with incrementally increasing CDR code values. A sequence or block of CDR code values corresponding to the eye-opening cause the frequencies of the cal_{clk} signal 830 and the rclk signal 810 to have matching frequencies.

At some point, the CDR code value is incremented to a level that causes the programmable delay circuit 822 to produce a delay that is too long and a loop frequency that is too low. The detection of a loop frequency that is too low may be associated with a second boundary of the eye-opening. The eye-opening may be identified or associated with the block of CDR code values that cause the frequencies of the cal_{clk} signal 830 and the rclk signal 810 to have matching frequencies.

After completing each sweep, the CDR calibration logic circuit 816 may compare the CDR code used to configure to the programmable delay circuit 622 in the mission clock generation subcircuit 608 with the block of CDR code values corresponding to the eye-opening. In some instances, the CDR calibration logic circuit 816 may reconfigure the programmable delay circuit 622 in the mission clock generation subcircuit 608 with a CDR code value that is closer to the median CDR code value in the block of CDR code values. In some implementations, the programmable delay circuit 622 in the mission clock generation subcircuit 608 may be continuously recalibrated by continuously sweeping the possible or available values for the CDR_{cal} code 838 in clock generation subcircuit 808.

The results 904, 924 shown in FIG. 9 illustrate examples in which a range of values 910, 930 of CDR code values can be associated with the eye-opening. The values of the CDR code 902, 922 within these blocks of values are expected to provide a sampling clock edge that lies within the eye opening. The values of the CDR code 902, 922 can be used to calculate the delay between first-occurring zero crossings of signaling state in the difference signals 802a, 802b, 802c and the sampling clock edge. Accordingly, the combination of results 904 and CDR code 902 values can serve as a proxy for time-based eye-opening measurements.

With continued reference to FIG. 8, the calibration procedures using the CDR 800 can be performed during normal operations, without stalling the C-PHY communication link. The multiplexing circuit 812 may be configured to enable the duplicate clock generation subcircuit 808 to perform a dynamic version of the calibration procedure while the mission clock generation subcircuit 608 is functioning in a normal mode of operation. In the illustrated example, the duplicate clock generation subcircuit 808 may be recalibrated by performing a sweep of possible or available values for the CDR_{cal} code 838 to determine an optimal delay setting for the programmable delay circuit 822 in the duplicate clock generation subcircuit 808. The programmable delay circuit 622 in the mission clock generation subcircuit 608 may be updated when the recalibration of the duplicate clock generation subcircuit 808 is completed.

In some implementations, recalibration of the duplicate clock generation subcircuit 808 is performed using live data, which may be defined as using the difference signals output by multiplexers 804. The CDR calibration logic circuit 816 may be configured to compare the receive clock signals output by the mission clock generation subcircuit 608 and the duplicate clock generation subcircuit 808 (i.e., the rclk signal 810 and the cal_{clk} signal 830) during calibration. The CDR calibration logic circuit 816 may identify a revised eye-opening associated for the C-PHY communication link and may reconfigure the programmable delay circuit 622 in the mission clock generation subcircuit 608 using a CDR code that corresponds to the center of the revised eye-opening.

In some implementations, the CDR calibration logic circuit 816 may decode data from the difference signals output by multiplexers 804. The decoded data may be checked for errors and a revised eye-opening may be determined or calculated using measured BER for each sweep.

In some implementations, recalibration of the duplicate clock generation subcircuit 808 is performed using C-PHY encoded signals 814 generated by the BIST 832, or by another source of C-PHY encoded test signals. In one example, the CDR calibration logic circuit 816 may be configured to generate the C-PHY encoded test signals. The CDR calibration logic circuit 816 may determine a revised eye-opening by comparing data decoded using the cal_{clk} signal 830 with original or expected data.

Dynamic CDR calibration performed in accordance with certain aspects of this disclosure can ensure that a CDR continuously operates within the eye opening and with sufficient margin to accommodate random jitter or noise. The use of the duplicate clock generation subcircuit 808 can accommodate PVT conditions that change during C-PHY link operation and can prevent deterioration of link reliability. For example, dynamic recalibration can respond to increases in measured BER and thereby avoid catastrophic functional conditions affecting the link and other worst-case issues. As noted herein, dynamic recalibration can provide a real-time eye-opening monitor feature without adding additional circuits and power consumption and without impacting CDR normal function.

Certain aspects of the presently disclosed dynamic calibration circuits and methods can enable a CDR to operate at increased signal-to-noise ratios (SNR) that are associated with increased symbol transmission rates. For example, certain C-PHY interfaces amplitude modulated the C-PHY signals, reducing the average and minimum signal amplitudes and thereby reducing SNR. Dynamic CDR calibration can maintain BER in the resultant challenging conditions.

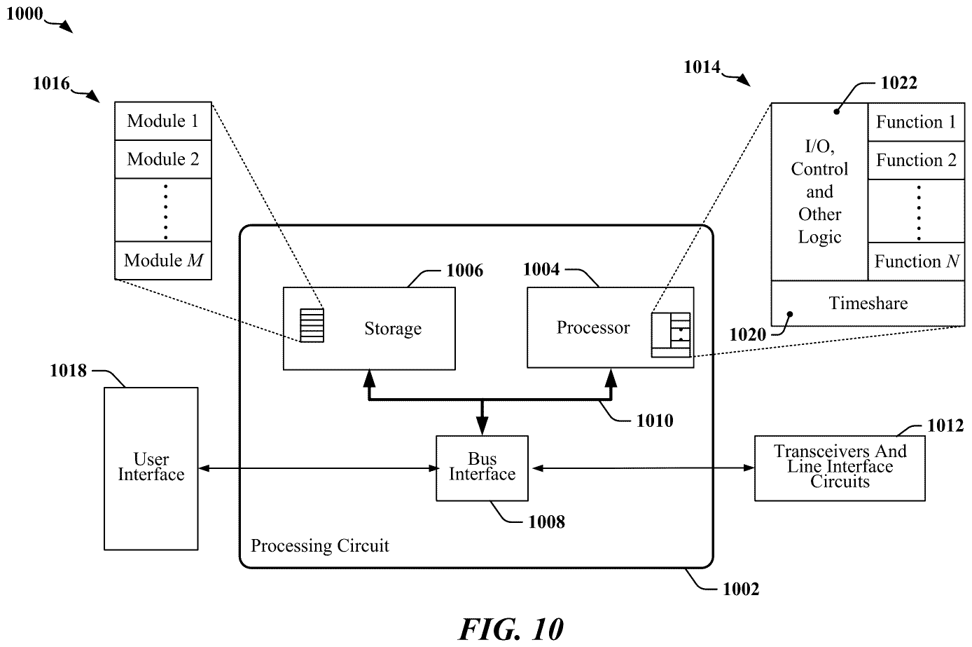

FIG. 10 is a conceptual diagram 1000 illustrating an example of a hardware implementation for an apparatus employing a processing circuit 1002 that may be configured to perform one or more functions disclosed herein. In accordance with various aspects of the disclosure, an element, or any portion of an element, or any combination of elements as disclosed herein may be implemented using the processing circuit 1002. The processing circuit 1002 may include certain devices, circuits, and/or logic that support the various encoding schemes disclosed herein. The processing circuit 1002 may include, configure and/or manage one or more of the circuits illustrated in FIG. 4, 6 or 8. In one example, the processing circuit 1002 may include some combination of circuitry and modules that facilitates the sampling and decoding of symbols that are encoded using C-PHY encoding, and which define three or more voltage levels on the wires of a serial bus. In another example, the processing circuit 1002 may include some combination of circuitry and modules that facilitates the generation of clock signals that can control efficient capture of C-PHY encoded symbols in accordance with certain aspects disclosed herein. The processing circuit 1002 may include a state machine or another type of processing device that manages encoding and/or decoding processes as disclosed herein.

The processing circuit 1002 may include one or more processors 1004 that are controlled by some combination of hardware and software modules. Examples of processors 1004 include microprocessors, microcontrollers, digital signal processors (DSPs), field programmable gate arrays (FPGAs), programmable logic devices (PLDs), state machines, sequencers, gated logic, discrete hardware circuits, and other suitable hardware configured to perform the various functionality described throughout this disclosure. The one or more processors 1004 may include specialized processors that perform specific functions, and that may be configured, augmented or controlled by one of the software modules 1016. The one or more processors 1004 may be configured through a combination of software modules 1016 loaded during initialization, and further configured by loading or unloading one or more software modules 1016 during operation.

In the illustrated example, the processing circuit 1002 may be implemented with a bus architecture, represented generally by the bus 1010. The bus 1010 may include any number of interconnecting buses and bridges depending on the specific application of the processing circuit 1002 and the overall design constraints. The bus 1010 links together various circuits including the one or more processors 1004, and a processor-readable storage medium 1006. The processor-readable storage medium 1006 may include memory devices and mass storage devices, and may be referred to herein as computer-readable media and/or processor-readable media. The bus 1010 may also link various other circuits such as timing sources, timers, peripherals, voltage regulators, and power management circuits. A bus interface 1008 may provide an interface between the bus 1010 and one or more transceivers 1012. A transceiver 1012 may be provided for each networking technology supported by the processing circuit. In some instances, multiple networking technologies may share some or all of the circuitry or processing modules found in a transceiver 1012. Each transceiver 1012 provides a means for communicating with various other apparatus over a transmission medium. Depending upon the nature of the apparatus, a user interface 1018 (e.g., keypad, display, speaker, microphone, joystick) may also be provided, and may be communicatively coupled to the bus 1010 directly or through the bus interface 1008.

A processor 1004 may be responsible for managing the bus 1010 and for general processing that may include the execution of software stored in a processor-readable medium that may include the processor-readable storage medium 1006. In this respect, the processing circuit 1002, including the processor 1004, may be used to implement any of the methods, functions and techniques disclosed herein. The processor-readable storage medium 1006 may be used for storing data that is manipulated by the processor 1004 when executing software, and the software may be configured to implement any one of the methods disclosed herein.

One or more processors 1004 in the processing circuit 1002 may execute software. Software shall be construed broadly to mean instructions, instruction sets, code, code segments, program code, programs, subprograms, software modules, applications, software applications, software packages, routines, subroutines, objects, executables, threads of execution, procedures, functions, algorithms, etc., whether referred to as software, firmware, middleware, microcode, hardware description language, or otherwise. The software may reside in computer-readable form in the processor-readable storage medium 1006 or in another, external processor-readable medium. The processor-readable storage medium 1006 may include a non-transitory processor-readable medium. A non-transitory processor-readable medium includes, by way of example, a magnetic storage device (e.g., hard disk, floppy disk, magnetic strip), an optical disk (e.g., a compact disc (CD) or a digital versatile disc (DVD)), a smart card, a flash memory device (e.g., a “flash drive,” a card, a stick, or a key drive), RAM, a ROM, a PROM, an erasable PROM (EPROM), an EEPROM, a register, a removable disk, and any other suitable medium for storing software and/or instructions that may be accessed and read by a computer. The processor-readable storage medium 1006 may also include, by way of example, a carrier wave, a transmission line, and any other suitable medium for transmitting software and/or instructions that may be accessed and read by a computer. Processor-readable storage medium 1006 may reside in the processing circuit 1002, in the processor 1004, external to the processing circuit 1002, or be distributed across multiple entities including the processing circuit 1002. The processor-readable storage medium 1006 may be embodied in a computer program product. By way of example, a computer program product may include a processor-readable medium in packaging materials. Those skilled in the art will recognize how best to implement the described functionality presented throughout this disclosure depending on the particular application and the overall design constraints imposed on the overall system.

The processor-readable storage medium 1006 may maintain software maintained and/or organized in loadable code segments, modules, applications, programs, etc., which may be referred to herein as software modules 1016. Each of the software modules 1016 may include instructions and data that, when installed or loaded on the processing circuit 1002 and executed by the one or more processors 1004, contribute to a run-time image 1014 that controls the operation of the one or more processors 1004. When executed, certain instructions may cause the processing circuit 1002 to perform functions in accordance with certain methods, algorithms and processes described herein.

Some of the software modules 1016 may be loaded during initialization of the processing circuit 1002, and these software modules 1016 may configure the processing circuit 1002 to enable performance of the various functions disclosed herein. For example, some software modules 1016 may configure internal devices and/or logic circuits 1022 of the processor 1004, and may manage access to external devices such as the transceiver 1012, the bus interface 1008, the user interface 1018, timers, mathematical coprocessors, and so on. The software modules 1016 may include a control program and/or an operating system that interacts with interrupt handlers and device drivers, and that controls access to various resources provided by the processing circuit 1002. The resources may include memory, processing time, access to the transceiver 1012, the user interface 1018, and so on.

One or more processors 1004 of the processing circuit 1002 may be multifunctional, whereby some of the software modules 1016 are loaded and configured to perform different functions or different instances of the same function. The one or more processors 1004 may additionally be adapted to manage background tasks initiated in response to inputs from the user interface 1018, the transceiver 1012, and device drivers, for example. To support the performance of multiple functions, the one or more processors 1004 may be configured to provide a multitasking environment, whereby each of a plurality of functions is implemented as a set of tasks serviced by the one or more processors 1004 as needed or desired. In one example, the multitasking environment may be implemented using a timesharing program 1020 that passes control of a processor 1004 between different tasks, whereby each task returns control of the one or more processors 1004 to the timesharing program 1020 upon completion of any outstanding operations and/or in response to an input such as an interrupt. When a task has control of the one or more processors 1004, the processing circuit is effectively specialized for the purposes addressed by the function associated with the controlling task. The timesharing program 1020 may include an operating system, a main loop that transfers control on a round-robin basis, a function that allocates control of the one or more processors 1004 in accordance with a prioritization of the functions, and/or an interrupt driven main loop that responds to external events by providing control of the one or more processors 1004 to a handling function.

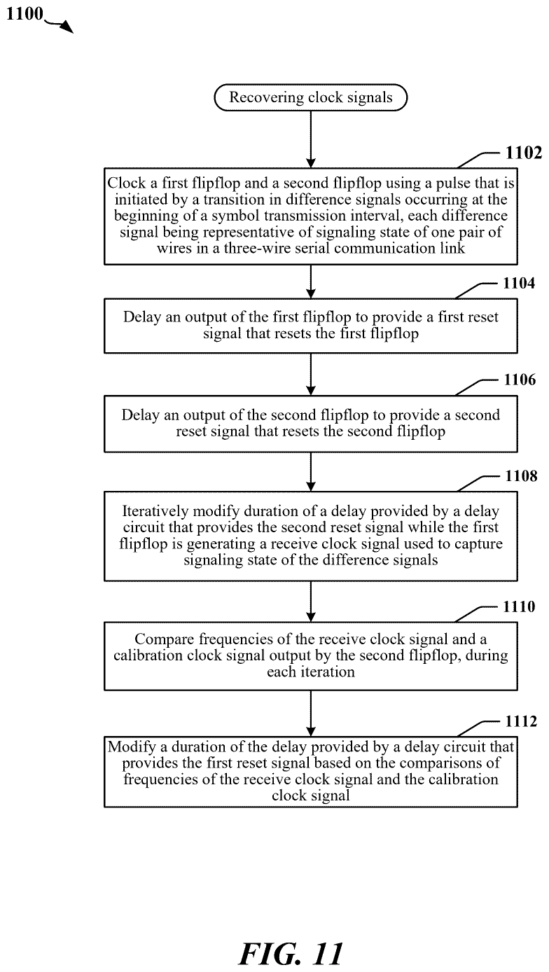

FIG. 11 is a flowchart 1100 of a method for recovering clock signals embedded in signaling received over a multi-wire serial bus in accordance with certain aspects of this disclosure. The method may relate to the operation of CDR, such as the CDR 800 illustrated in FIG. 8. In one example, the method may be implemented in a receiver coupled to a three-wire serial communication link operated in accordance with a MIPI Alliance C-PHY protocol.

At block 1102, a first flipflop and a second flipflop may be clocked using a pulse that is initiated by a transition in difference signals occurring at the beginning of a symbol transmission interval. Each difference signal may be representative of signaling state of one pair of wires in a three-wire serial communication link. Three difference signals may provide a comparisons for each of the three combinations of two wires in the trio 840 shown in FIG. 8.

At block 1104, an output of the first flipflop may be delayed to provide a first reset signal that resets the first flipflop, and at block 1106, an output of the second flipflop may be delayed to provide a second reset signal that resets the second flipflop.

At block 1108, the duration of a delay provided by the second delay circuit may be iteratively modified while the first flipflop is generating a receive clock signal used to capture signaling state of the difference signals. In one example, a sweep of possible or available delay curations may be performed by modifying the delay provided by the second delay circuit by a step delay in multiple iterations. The step delay may be a fixed duration. In some implementations, the step delay may increase or decrease between certain iterations.

At block 1110, the frequencies of the receive clock signal and a calibration clock signal may be compared. The calibration clock signal may be output by the second flipflop during each iteration. Comparisons may be made during each iteration of the sweep. Comparisons may be made after each incremental change in delay duration.

At block 1112, the duration of the delay provided by a delay circuit that provides the first reset signal may be modified based on the comparisons of frequencies of the receive clock signal and the calibration clock signal.

In some implementations, the duration of the delay provided by a delay circuit that provides the first reset signal is configured to suppress additional transitions occurring at the beginning of the symbol transmission interval. The duration of the delay provided by a delay circuit that provides the first reset signal may be configured with a desire to avoid suppressing one or more transitions at the beginning of a next and immediately following symbol transmission interval.

In certain implementations, the duration of the delay provided by the second delay circuit is incrementally modified by incrementally modifying a calibration codeword. A block of calibration codewords that cause the frequency of the calibration clock signal to match the frequency of the receive clock signal may be identified. In some examples, the duration of the delay provided by a delay circuit that provides the first reset signal is modified by configuring the first delay circuit with a codeword that corresponds to a median value of the block of calibration codewords. In various example, a first block of calibration codewords causes the frequency of the calibration clock signal to be greater than the frequency of the receive clock signal, a second block of calibration codewords causes the frequency of the calibration clock signal to match the frequency of the receive clock signal, and a third block of calibration codewords causes the frequency of the calibration clock signal to be less than the frequency of the receive clock signal.

An apparatus configured or adapted in accordance with certain aspects of this disclosure includes means for generating pulses in response to first-occurring transitions in difference signals, each difference signal being representative of signaling state of one pair of wires in a three-wire serial communication link. In one example, the three-wire serial communication link is configured to be operated in accordance with a MIPI Alliance C-PHY protocol. The apparatus may also include means for calibrating a first delay circuit in a first clock generation subcircuit, including a second clock generation subcircuit and a calibration subcircuit. The calibration subcircuit may be configured to iteratively modify duration of a delay provided by a second delay circuit while the first clock generation subcircuit is generating a receive clock signal used to capture signaling state of the difference signals, compare a frequency of the receive clock signal with a frequency of a calibration clock signal output by the second clock generation subcircuit, during each iteration, and modify a duration of the delay provided by the first delay circuit based on the comparisons of frequencies of the receive clock signal and the calibration clock signal.

In some implementations, the duration of each of the pulses is controlled by the delay provided by the first delay circuit. The duration of the delay provided by the first delay circuit may be configured to suppress additional transitions occurring at the beginning of a symbol transmission interval without suppressing a transition at the beginning of a next and immediately following symbol transmission interval.

In some implementations, the calibration subcircuit is further configured to modify the duration of the delay provided by the second delay circuit in each iteration by incrementally modifying a calibration codeword used to configure duration of the delay provided by the second delay circuit, and identify a block of calibration codewords that cause the frequency of the calibration clock signal to match the frequency of the receive clock signal. The calibration subcircuit may be further configured to modify the duration of the delay provided by the first delay circuit by configuring the first delay circuit with a codeword that corresponds to a median value of the block of calibration codewords.

In certain implementations, a first block of calibration codewords causes the frequency of the calibration clock signal to be greater than the frequency of the receive clock signal, a second block of calibration codewords causes the frequency of the calibration clock signal to match the frequency of the receive clock signal, and a third block of calibration codewords causes the frequency of the calibration clock signal to be less than the frequency of the receive clock signal.

A clock recovery circuit for a C-PHY interface includes clock generation subcircuits and a calibration circuit. A first clock generation subcircuit has a flipflop and a delay circuit. The flipflop in the first clock generation subcircuit is clocked by pulses initiated by transitions in difference signals. Each difference signal may be representative of signaling state of one pair of wires in a trio used for a C-PHY communication link. A delay circuit in the first clock generation subcircuit may be configured to delay an output of the flipflop in the first clock generation subcircuit, and to provide a first reset signal coupled to a reset input of the flipflop in the first clock generation subcircuit. A second clock generation subcircuit has a flipflop and a delay circuit that may be replicas of the flipflop and a delay circuit in the first clock generation subcircuit. The flipflop in the second clock generation subcircuit is clocked by the pulses. The delay circuit in the second clock generation subcircuit may be configured to delay an output of the flipflop in the second clock generation subcircuit, and to provide a reset signal to a reset input of the flipflop in the second clock generation subcircuit.

The calibration subcircuit may be configured to iteratively modify duration of a delay provided by the delay circuit in the second clock generation subcircuit while the first clock generation subcircuit is generating a receive clock signal used to capture signaling state of the difference signals. During each iteration, the calibration subcircuit may compare a frequency of the receive clock signal with a frequency of a calibration clock signal output by the second clock generation subcircuit. The calibration subcircuit may be configured to modify a duration of the delay provided by the delay circuit in the first clock generation subcircuit based on the comparisons of frequencies of the receive clock signal and the calibration clock signal.

In some implementations, each of the pulses is initiated by a transition occurring at the beginning of a symbol transmission interval. The duration of the delay provided by the delay circuit in the first clock generation subcircuit may be configured to suppress additional transitions occurring at the beginning of the symbol transmission interval without suppressing transitions at the beginning of a next and immediately following symbol transmission interval.

In certain implementations, the calibration subcircuit is further configured to incrementally modify the duration of the delay provided by the delay circuit in the second clock generation subcircuit by incrementally modifying a calibration codeword used to configure duration of the delay provided by the second delay circuit. The calibration subcircuit may be further configured to identify a block of calibration codewords that cause the frequency of the calibration clock signal to match the frequency of the receive clock signal. The calibration subcircuit may be further configured to modify the duration of the delay provided by the delay circuit in the first clock generation subcircuit by configuring delay circuit in the first clock generation subcircuit with a codeword that corresponds to a median value of the block of calibration codewords.

In certain examples, a first block of calibration codewords causes the frequency of the calibration clock signal to be greater than the frequency of the receive clock signal, a second block of calibration codewords causes the frequency of the calibration clock signal to match the frequency of the receive clock signal, and a third block of calibration codewords causes the frequency of the calibration clock signal to be less than the frequency of the receive clock signal. In one example, each calibration codeword in the second block of calibration codewords encodes a value that is greater than the value encoded by each calibration codeword in the first block of calibration codewords and less than the value encoded by each calibration codeword in the third block of calibration codewords. In another example, each calibration codeword in the second block of calibration codewords encodes a value that is less than the value encoded by each calibration codeword in the first block of calibration codewords and greater than the value encoded by each calibration codeword in the third block of calibration codewords.

Some implementation examples are described in the following numbered clauses:
1. A clock recovery circuit comprising: a first clock generation subcircuit that includes a first flipflop that is clocked by pulses initiated by transitions in difference signals, each difference signal being representative of signaling state of one pair of wires in a three-wire serial communication link, and a first delay circuit that delays an output of the first flipflop to provide a first reset signal that resets the first flipflop; a second clock generation subcircuit that includes a second flipflop that is clocked by the pulses, and a second delay circuit that delays an output of the second flipflop to provide a second reset signal that resets the second flipflop; a calibration subcircuit configured to: iteratively modify duration of a delay provided by the second delay circuit while the first clock generation subcircuit is generating a receive clock signal used to capture signaling state of the difference signals; compare a frequency of the receive clock signal with a frequency of a calibration clock signal output by the second clock generation subcircuit, during each iteration; and modify a duration of the delay provided by the first delay circuit based on comparisons of frequencies of the receive clock signal and the calibration clock signal.
2. The clock recovery circuit as described in clause 1, wherein each of the pulses is initiated by a transition occurring at the beginning of a symbol transmission interval, and wherein the duration of the delay provided by the first delay circuit is configured to suppress additional transitions occurring at the beginning of the symbol transmission interval without suppressing a transition at the beginning of a next and immediately following symbol transmission interval.
3. The clock recovery circuit as described in clause 1 or clause 2, wherein the calibration subcircuit is further configured to: modify the duration of the delay provided by the second delay circuit in each iteration by incrementally modifying a calibration codeword used to configure duration of the delay provided by the second delay circuit; and identify a block of calibration codewords that cause the frequency of the calibration clock signal to match the frequency of the receive clock signal.
4. The clock recovery circuit as described in clause 3, wherein the calibration subcircuit is further configured to: modify the duration of the delay provided by the first delay circuit by configuring the first delay circuit with a codeword that corresponds to a median value of the block of calibration codewords.
5. The clock recovery circuit as described in clause 3 or clause 4, wherein a first block of calibration codewords causes the frequency of the calibration clock signal to be greater than the frequency of the receive clock signal, a second block of calibration codewords causes the frequency of the calibration clock signal to match the frequency of the receive clock signal, and a third block of calibration codewords causes the frequency of the calibration clock signal to be less than the frequency of the receive clock signal.
6. The clock recovery circuit as described in clause 5, wherein each calibration codeword in the second block of calibration codewords encodes a value that is greater than the value encoded by each calibration codeword in the first block of calibration codewords and less than the value encoded by each calibration codeword in the third block of calibration codewords.
7. The clock recovery circuit as described in clause 5, wherein each calibration codeword in the second block of calibration codewords encodes a value that is less than the value encoded by each calibration codeword in the first block of calibration codewords and greater than the value encoded by each calibration codeword in the third block of calibration codewords.
8. The clock recovery circuit as described in any of clauses 1-7, wherein the three-wire serial communication link is operated in accordance with a Mobile Industry Processor Interface (MIPI) Alliance C-PHY protocol.
9. An apparatus, comprising: means for generating pulses in response to first-occurring transitions in difference signals, each difference signal being representative of signaling state of one pair of wires in a three-wire serial communication link; and means for calibrating a first delay circuit in a first clock generation subcircuit, the means for calibrating including a second clock generation subcircuit and a calibration subcircuit, wherein the calibration subcircuit is configured to: iteratively modify duration of a delay provided by a second delay circuit while the first clock generation subcircuit is generating a receive clock signal used to capture signaling state of the difference signals; compare a frequency of the receive clock signal with a frequency of a calibration clock signal output by the second clock generation subcircuit, during each iteration; and modify a duration of the delay provided by the first delay circuit based on comparisons of frequencies of the receive clock signal and the calibration clock signal.
10. The apparatus as described in clause 9, wherein the duration of each of the pulses is controlled by the delay provided by the first delay circuit, and wherein the duration of the delay provided by the first delay circuit is configured to suppress additional transitions occurring at the beginning of a symbol transmission interval without suppressing a transition at the beginning of a next and immediately following symbol transmission interval.
11. The apparatus as described in clause 9 or clause 10, wherein the calibration subcircuit is further configured to: modify the duration of the delay provided by the second delay circuit in each iteration by incrementally modifying a calibration codeword used to configure duration of the delay provided by the second delay circuit; and identify a block of calibration codewords that cause the frequency of the calibration clock signal to match the frequency of the receive clock signal.
12. The apparatus as described in clause 11, wherein the calibration subcircuit is further configured to: modify the duration of the delay provided by the first delay circuit by configuring the first delay circuit with a codeword that corresponds to a median value of the block of calibration codewords.
13. The apparatus as described in clause 11 or clause 12, wherein a first block of calibration codewords causes the frequency of the calibration clock signal to be greater than the frequency of the receive clock signal, a second block of calibration codewords causes the frequency of the calibration clock signal to match the frequency of the receive clock signal, and a third block of calibration codewords causes the frequency of the calibration clock signal to be less than the frequency of the receive clock signal.
14. The apparatus as described in any of clauses 9-13, wherein the three-wire serial communication link is operated in accordance with a Mobile Industry Processor Interface (MIPI) Alliance C-PHY protocol.
15. A method for recovering clock signals, comprising: clocking a first flipflop and a second flipflop using a pulse that is initiated by a transition in difference signals occurring at the beginning of a symbol transmission interval, each difference signal being representative of signaling state of one pair of wires in a three-wire serial communication link; delaying an output of the first flipflop to provide a first reset signal that resets the first flipflop; delaying an output of the second flipflop to provide a second reset signal that resets the second flipflop; iteratively modifying duration of a delay provided by a delay circuit that provides the second reset signal while the first flipflop is generating a receive clock signal used to capture signaling state of the difference signals; comparing frequencies of the receive clock signal and a calibration clock signal output by the second flipflop, during each iteration; and modifying a duration of the delay provided by a delay circuit that provides the first reset signal based on comparisons of frequencies of the receive clock signal and the calibration clock signal.
16. The method as described in clause 15, wherein the duration of the delay provided by a delay circuit that provides the first reset signal is configured to suppress additional transitions occurring at the beginning of the symbol transmission interval without suppressing a transition at the beginning of a next and immediately following symbol transmission interval.
17. The method as described in clause 15 or clause 16, further comprising: modifying the duration of the delay provided by the second delay circuit in each iteration by incrementally modifying a calibration codeword used to configure duration of the delay provided by the second delay circuit; and identifying a block of calibration codewords that cause the frequency of the calibration clock signal to match the frequency of the receive clock signal.
18. The method as described in clause 17, further comprising: modifying the duration of the delay provided by a delay circuit that provides the first reset signal by configuring the first delay circuit with a codeword that corresponds to a median value of the block of calibration codewords.
19. The method as described in clause 17 or clause 18, wherein a first block of calibration codewords causes the frequency of the calibration clock signal to be greater than the frequency of the receive clock signal, a second block of calibration codewords causes the frequency of the calibration clock signal to match the frequency of the receive clock signal, and a third block of calibration codewords causes the frequency of the calibration clock signal to be less than the frequency of the receive clock signal. 20. The method as described in any of clauses 15-19, wherein the three-wire serial communication link is operated in accordance with a Mobile Industry Processor Interface (MIPI) Alliance C-PHY protocol.

It is understood that the specific order or hierarchy of steps in the processes disclosed is an illustration of exemplary approaches. Based upon design preferences, it is understood that the specific order or hierarchy of steps in the processes may be rearranged. Further, some steps may be combined or omitted. The accompanying method claims present elements of the various steps in a sample order, and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” Unless specifically stated otherwise, the term “some” refers to one or more. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed as a means plus function unless the element is expressly recited using the phrase “means for.”

What is claimed is:

1. A clock recovery circuit comprising:
a first clock generation subcircuit that includes
a first flipflop that is clocked by pulses initiated by transitions in difference signals, each difference signal being representative of signaling state of one pair of wires in a three-wire serial communication link, and
a first delay circuit that delays an output of the first flipflop to provide a first reset signal that resets the first flipflop;
a second clock generation subcircuit that includes
a second flipflop that is clocked by the pulses, and
a second delay circuit that delays an output of the second flipflop to provide a second reset signal that resets the second flipflop;
a calibration subcircuit configured to:
iteratively modify duration of a delay provided by the second delay circuit while the first clock generation subcircuit is generating a receive clock signal used to capture signaling state of the difference signals;
compare a frequency of the receive clock signal with a frequency of a calibration clock signal output by the second clock generation subcircuit, during each iteration; and
modify a duration of the delay provided by the first delay circuit based on comparisons of frequencies of the receive clock signal and the calibration clock signal.

2. The clock recovery circuit of claim 1, wherein each of the pulses is initiated by a transition occurring at the beginning of a symbol transmission interval, and wherein the duration of the delay provided by the first delay circuit is configured to suppress additional transitions occurring at the beginning of the symbol transmission interval without suppressing a transition at the beginning of a next and immediately following symbol transmission interval.

3. The clock recovery circuit of claim 1, wherein the calibration subcircuit is further configured to:
modify the duration of the delay provided by the second delay circuit in each iteration by incrementally modifying a calibration codeword used to configure duration of the delay provided by the second delay circuit; and
identify a block of calibration codewords that cause the frequency of the calibration clock signal to match the frequency of the receive clock signal.

4. The clock recovery circuit of claim 3, wherein the calibration subcircuit is further configured to:
modify the duration of the delay provided by the first delay circuit by configuring the first delay circuit with a codeword that corresponds to a median value of the block of calibration codewords.

5. The clock recovery circuit of claim 3, wherein a first block of calibration codewords causes the frequency of the calibration clock signal to be greater than the frequency of the receive clock signal, a second block of calibration codewords causes the frequency of the calibration clock signal to match the frequency of the receive clock signal, and a third block of calibration codewords causes the frequency of the calibration clock signal to be less than the frequency of the receive clock signal.

6. The clock recovery circuit of claim 5, wherein each calibration codeword in the second block of calibration codewords encodes a value that is greater than the value encoded by each calibration codeword in the first block of calibration codewords and less than the value encoded by each calibration codeword in the third block of calibration codewords.

7. The clock recovery circuit of claim 5, wherein each calibration codeword in the second block of calibration codewords encodes a value that is less than the value encoded by each calibration codeword in the first block of calibration codewords and greater than the value encoded by each calibration codeword in the third block of calibration codewords.

8. The clock recovery circuit of claim 1, wherein the three-wire serial communication link is operated in accordance with a Mobile Industry Processor Interface (MIPI) Alliance C-PHY protocol.

9. An apparatus, comprising:
means for generating pulses in response to first-occurring transitions in difference signals, each difference signal being representative of signaling state of one pair of wires in a three-wire serial communication link; and
means for calibrating a first delay circuit in a first clock generation subcircuit, the means for calibrating including a second clock generation subcircuit and a calibration subcircuit, wherein the calibration subcircuit is configured to:
iteratively modify duration of a delay provided by a second delay circuit while the first clock generation subcircuit is generating a receive clock signal used to capture signaling state of the difference signals;
compare a frequency of the receive clock signal with a frequency of a calibration clock signal output by the second clock generation subcircuit, during each iteration; and
modify a duration of the delay provided by the first delay circuit based on comparisons of frequencies of the receive clock signal and the calibration clock signal.

10. The apparatus of claim 9, wherein the duration of each of the pulses is controlled by the delay provided by the first delay circuit, and wherein the duration of the delay provided by the first delay circuit is configured to suppress additional transitions occurring at the beginning of a symbol transmission interval without suppressing a transition at the beginning of a next and immediately following symbol transmission interval.

11. The apparatus of claim 9, wherein the calibration subcircuit is further configured to:
modify the duration of the delay provided by the second delay circuit in each iteration by incrementally modifying a calibration codeword used to configure duration of the delay provided by the second delay circuit; and
identify a block of calibration codewords that cause the frequency of the calibration clock signal to match the frequency of the receive clock signal.

12. The apparatus of claim 11, wherein the calibration subcircuit is further configured to:
modify the duration of the delay provided by the first delay circuit by configuring the first delay circuit with a codeword that corresponds to a median value of the block of calibration codewords.

13. The apparatus of claim 11, wherein a first block of calibration codewords causes the frequency of the calibration clock signal to be greater than the frequency of the receive clock signal, a second block of calibration codewords causes the frequency of the calibration clock signal to match the frequency of the receive clock signal, and a third block of calibration codewords causes the frequency of the calibration clock signal to be less than the frequency of the receive clock signal.

14. The apparatus of claim 9, wherein the three-wire serial communication link is operated in accordance with a Mobile Industry Processor Interface (MIPI) Alliance C-PHY protocol.

15. A method for recovering clock signals, comprising:
clocking a first flipflop and a second flipflop using a pulse that is initiated by a transition in difference signals occurring at the beginning of a symbol transmission interval, each difference signal being representative of signaling state of one pair of wires in a three-wire serial communication link;
delaying an output of the first flipflop to provide a first reset signal that resets the first flipflop;
delaying an output of the second flipflop to provide a second reset signal that resets the second flipflop;
iteratively modifying duration of a delay provided by a first delay circuit that provides the second reset signal while the first flipflop is generating a receive clock signal used to capture signaling state of the difference signals;
comparing frequencies of the receive clock signal and a calibration clock signal output by the second flipflop, during each iteration; and
modifying a duration of the delay provided by a second delay circuit that provides the first reset signal based on comparisons of frequencies of the receive clock signal and the calibration clock signal.

16. The method of claim 15, wherein the duration of the delay provided by the second delay circuit is configured to suppress additional transitions occurring at the beginning of the symbol transmission interval without suppressing a transition at the beginning of a next and immediately following symbol transmission interval.

17. The method of claim 15, further comprising:
modifying the duration of the first delay circuit by incrementally modifying a calibration codeword used to configure duration of the delay provided by the first delay circuit; and
identifying a block of calibration codewords that cause the frequency of the calibration clock signal to match the frequency of the receive clock signal.

18. The method of claim 17, further comprising:
modifying the duration of the delay provided by the second delay circuit by configuring the second delay circuit with a codeword that corresponds to a median value of the block of calibration codewords.

19. The method of claim 17, wherein a first block of calibration codewords causes the frequency of the calibration clock signal to be greater than the frequency of the receive clock signal, a second block of calibration codewords causes the frequency of the calibration clock signal to match the frequency of the receive clock signal, and a third block of calibration codewords causes the frequency of the calibration clock signal to be less than the frequency of the receive clock signal.

20. The method of claim 15, wherein the three-wire serial communication link is operated in accordance with a Mobile Industry Processor Interface (MIPI) Alliance C-PHY protocol.
